(19) United States
(12) Patent Application Publication
(10) Pub. No.: US 2018/0261481 A1
(43) Pub. Date: Sep. 13, 2018

(54) SENSING SYSTEM, SENSING WAFER, AND PLASMA PROCESSING APPARATUS

(71) Applicant: Toshiba Memory Corporation, MInato-ku (JP)

(72) Inventor: Hideo ETO, Yokkaichi (JP)

(73) Assignee: Toshiba Memory Corporation, Minato-ku (JP)

(21) Appl. No.: 15/704,711

(22) Filed: Sep. 14, 2017

(30) Foreign Application Priority Data
Mar. 10, 2017 (JP) 2017-046030

(51) Int. Cl. H01L 21/67; H01J 37/32; H01J 37/305; G01K 11/32; G01L 1/24

(52) U.S. Cl. CPC H01L 21/67248; H01L 21/67288; H01L 21/67069; H01J 37/32889; H01J 2237/334; H01J 37/32091; G01K 11/32; G01L 1/242; H01J 37/3056

(57) ABSTRACT

According to one embodiment, a sensing system includes a waveguide, an optical system, and a detector. The waveguide is configured to guide light in a wafer. The optical system is configured to cause the light guided by the waveguide to go out from a back side of the wafer. The detector is configured to detect a state inside or outside the wafer based on a detection result about the light caused to go out by the optical system.

### CROSS-REFERENCE TO RELATED APPLICATIONS

This application is based upon and claims the benefit of priority front Japanese Patent Application No. 2017-046030, filed on Mar. 10, 2017; the entire contents of which are incorporated herein by reference.

### FIELD

Embodiments described herein relate generally to a sensing system, a sensing wafer, and a plasma processing apparatus.

### BACKGROUND

In order to monitor temperature in a plasma process, there is a method in which a thermo couple or thermo-label is provided in a plasma processing apparatus.

### BRIEF DESCRIPTION OF THE DRAWINGS

FIG. 1 is a sectional view illustrating a schematic configuration of a semiconductor manufacturing apparatus to which a temperature measuring system according to a first embodiment is applied;

FIG. 2A is a plan view illustrating a schematic configuration of a sensing wafer to be applied to the temperature measuring system according to the first embodiment;

FIG. 2B is a sectional view illustrating a schematic configuration of the sensing wafer of FIG. 2A;

FIG. 2C is a sectional view illustrating a wave-guiding state of an incoming light and an outgoing light inside an optical fiber provided in the sensing wafer of FIG. 2B (portion X);

FIGS. 3A and 3B are graphs illustrating the relationship between the temperature and phosphorescence decay time of a fluorescent substance used as an excitation light emitter in the temperature measuring system or FIG. 1;

FIG. 4A is a sectional view illustrating a state of the incoming light coming into the sensing wafer;

FIG. 4B is a sectional view illustrating a state of the outgoing light going out from the sensing wafer;

FIG. 4C illustrates the waveforms of the incoming light to the sensing wafer and the outgoing light from the sensing wafer;

FIG. 5A is a graph illustrating the relationship between the temperature and wavelength of a single-crystalline semiconductor lysed in the temperature measuring system of FIG. 1;

FIG. 5B is a graph illustrating the relationship between the temperature and wavelength peak intensity ratio of a fluorescent substance used as an excitation light emitter in the temperature measuring system of FIG. 1;

FIG. 5C is a graph illustrating the relationship between the temperature, wavelength, and intensity of the fluorescent substance used as an excitation light emitter in the temperature measuring system of FIG. 1;

FIG. 6A is a perspective view illustrating the incoming paths of incoming lights and the outgoing paths of outgoing lights in a case where a plurality of temperature measurement points are present on the sensing wafer;

FIG. 6B illustrates the waveforms of the incoming lights at the respective temperature measurement points and the waveforms of the outgoing lights from the respective temperature measurement points in the case where a plurality of temperature measurement points are present on the sensing wafer;

FIG. 7A is a plan view illustrating a schematic configuration of a sensing wafer to he applied to a temperature measuring system according to a second embodiment;

FIG. 7B is a sectional view illustrating a schematic configuration of the temperature measuring system according to the second embodiment;

FIG. 7C is a plan view illustrating a schematic configuration of an optical system at the midmost part of the sensing wafer of FIG. 7B;

FIG. 7D is a sectional view illustrating a schematic configuration of the optical system at the midmost part of the sensing wafer of FIG. 7E;

FIGS. 8A to 8E are sectional views illustrating a method of manufacturing a sensing wafer according to a third embodiment;

FIGS. 9A to 9E are sectional views illustrating a method of manufacturing a sensing wafer according to a fourth embodiment;

FIG. 10A is a plan view illustrating a schematic configuration of a sensing wafer to be applied to a sensing system according to a fifth embodiment;

FIG. 10B is a sectional view illustrating a schematic configuration of the sensing system according to the fifth embodiment;

FIG. 10C is a sectional view illustrating an application example of the sensing system according to the fifth embodiment;

FIG. 11A is a plan view illustrating a schematic configuration of a sensing wafer to be applied to a sensing system according to a sixth embodiment;

FIG. 11B is a sectional view illustrating a schematic configuration of the sensing system according to the sixth embodiment;

FIG. 11C is a sectional view illustrating an application example of the sensing system according to the sixth embodiment;

FIGS. 11D to 11F are plan views illustrating configuration examples of a probe used in an optical fiber distance meter of FIG. 11B;

FIG. 12A is a plan view illustrating a schematic configuration of a sensing wafer to be applied to a sensing system according to a seventh embodiment;

FIG. 12B is a sectional view illustrating a schematic configuration of the sensing system according to the seventh embodiment;

FIG. 12C is a sectional view illustrating an application example of the sensing system according to the seventh embodiment;

FIG. 13A is a plan view illustrating a schematic configuration of a sensing wafer to be applied to a sensing system according to an eighth embodiment;

FIG. 13B is a sectional view illustrating a schematic configuration of the sensing system according to the eighth embodiment;

FIG. 13C is a diagram illustrating the relationship between stress measured by the sensing system according to the eighth embodiment and Raman shift;

FIG. 14A is a plan view illustrating a schematic configuration of a sensing wafer to be applied to a plasma processing apparatus according to a ninth embodiment;

FIG. 14B is a sectional view illustrating a schematic configuration of a temperature measuring system in a case where the sensing wafer of FIG. 14A is applied to the plasma processing apparatus;

FIG. 14C is a sectional view illustrating an optical waveguide part of FIG. 14B in an enlarged state;

FIG. 14D is a sectional view illustrating a contact state of a wafer with a pin in moving the wafer up/down;

FIG. 15A is a plan view illustrating a schematic configuration of a sensing wafer to he applied to a plasma processing apparatus according to a tenth embodiment;

FIG. 15B is a sectional view illustrating a schematic configuration of a temperature measuring system in a case where the sensing wafer of FIG. 15A is applied to the plasma processing apparatus;

FIG. 15C is a sectional view illustrating an optical waveguide part of FIG. 15B in an enlarged state;

FIG. 16A is a plan view illustrating an arrangement example of pins on an electrostatic chuck applied to a plasma processing apparatus according to an eleventh embodiment;

FIG. 16B is a sectional view illustrating the positions of the pins before observation of a focus ring performed by a sensing system applied to the plasma processing apparatus according to the eleventh embodiment;

FIG. 16C is a sectional view illustrating the positions of the pins in observation of the focus ring performed by the sensing system applied to the plasma processing apparatus according to the eleventh embodiment;

FIG. 17A is a sectional view illustrating a state of observation of the focus ring performed by the sensing system applied to the plasma processing apparatus according to the eleventh embodiment;

FIG. 17B illustrates a sectional view of a state of the focus ring and a diagram of a state of the inner peripheral surface of the focus ring of FIG. 17A before its wear-out;

FIG. 17C illustrates a sectional view of a state of the focus ring and a diagram of a state of the inner peripheral surface of the focus ring of FIG. 17A after its wear-out;

FIG. 18A illustrates a sectional view of a state of the focus ring and the relationship between light intensity and height in observation of the inner peripheral surface of the focus ring of FIG. 17A before its wear-out;

FIG. 18B illustrates a sectional view of a state of the focus ring and the relationship between light intensity and height in observation of the inner peripheral surface of the focus ring of FIG. 17A in the case where its wear-out has progressed to some extent;

FIG. 18C illustrates a sectional view of a state of the focus ring and the relationship between light intensity and height in observation of the inner peripheral surface of the focus ring of FIG. 17A in the case where its wear-out has progressed further;

FIG. 18D is a diagram illustrating the relationship between light intensity and height in observation of the inner peripheral surface of the focus ring, in accordance with the degree of its wear-out;

FIG. 19A is a plan view illustrating an arrangement example of pins on an electrostatic chuck applied to a plasma processing apparatus according to a twelfth embodiment;

FIGS. 19B to 19D are sectional views illustrating a method of setting the height of observation of the focus ring performed by a sensing system applied to the plasma processing apparatus according to the twelfth embodiment;

FIG. 20A is a plan view illustrating a schematic configuration of a sensing wafer to be applied to a plasma processing apparatus according to a thirteenth embodiment;

FIG. 20B is a sectional view illustrating the relationship between the sensing wafer and the focus ring in a case where the sensing wafer of FIG. 20A is applied to the plasma processing apparatus;

FIG. 20C is a sectional view illustrating an optical waveguide part of FIG. 20B in an enlarged state;

FIG. 21A is a sectional view illustrating the relationship between a sensing wafer, which is to be applied to a plasma processing apparatus according to a fourteenth embodiment, and the focus ring, in a case where the sensing wafer is applied to the plasma processing apparatus; and

FIG. 21B is a sectional view illustrating an optical waveguide part of FIG. 21A in an enlarged state.

### DETAILED DESCRIPTION

In general, according to one embodiment, a sensing system includes a waveguide, an optical system, and a detector. The waveguide is configured to guide light in a wafer. The optical system is configured to cause the light guided by the waveguide to go out from a back side of the wafer. The detector is configured to detect a state inside or outside the wafer based on a detection result about the light caused to go out by the optical system.

Exemplary embodiments of a sensing system, a sensing wafer, and a plasma processing apparatus will be explained below in detail with reference to the accompanying drawings. The present invention is not limited to the following embodiments.

### First Embodiment

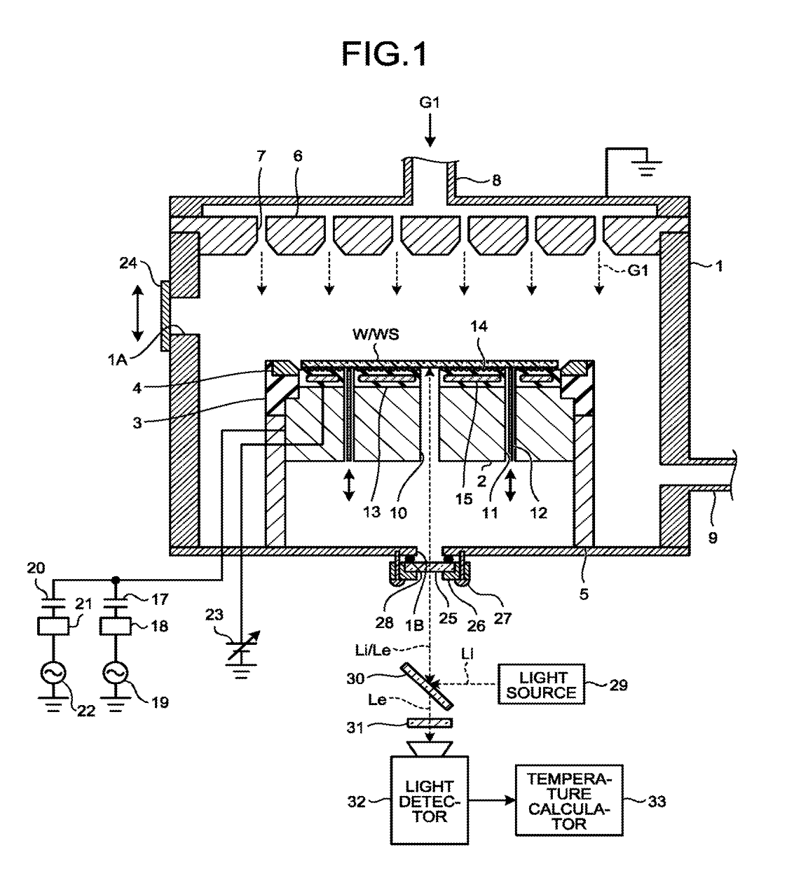

FIG. 1 is a sectional view illustrating a schematic configuration of a semiconductor manufacturing apparatus to which a temperature measuring system according to a first embodiment is applied. In FIG. 1, the semiconductor manufacturing apparatus is exemplified by a plasma etching apparatus of the capacitive coupling type (parallel plate type).

As illustrated in FIG. 1, the plasma etching apparatus is equipped with a chamber 1 for accommodating a wafer W or sensing wafer WS. The wafer W can be used for forming thereon a device, such as a transistor, memory, or integrated circuit.

Hereinafter, an explanation will be given of a method of using the sensing wafer WS to measure a temperature inside the chamber 1 during a plasma process.

For the substrate of the wafer W and the substrate of the sensing wafer WS, the same material may be used. For example, where the substrate of the wafer W is Si, Si may be used as the substrate of the sensing wafer WS. Where the substrata of the wafer W is GaAs, GaAs may be used as the substrate of the sensing wafer WS. Where the substrate of the wafer W is quartz, quartz may be used as the substrate of the sensing wafer WS.

When the temperature is to be measured by the sensing wafer WS, the process conditions may be set the same as those for forming devices on the wafer W. For example, in a case where management is conducted on the temperature for performing a hole process to a stacked structure of SiO₂ and SiN on the wafer W, the same power and etching gas as those of the hole process on the wafer N may be supplied when the temperature is to be measured by the sensing wafer WS.

Here, an explanation will be given of a case where the sensing wafer WS has been placed inside the chamber 1.

Inside the chamber 1, a pedestal 2 for holding the sensing wafer WS is provided. The chamber 1 and the pedestal 2 may be made of a conductive material, such as aluminum (Al). The chamber 1 may be grounded. The pedestal 2 is held by a support body 5 inside the chamber 1. An insulating ring 3 is provided around the pedestal 2. At the boundary between the pedestal and the insulating ring 3, a focus ring (which will also be referred to as “edge ring”) 4 is embedded along the outer periphery of the sensing wafer WS. The focus ring 4 can prevent an electric field from being deflected at the peripheral edge of the sensing wafer WS. The focus ring 4 can be replaced.

A showerhead 6 is provided on the upper part inside the chamber 1. The showerhead 6 can spout a gas G1 toward the wafer surface from above the sensing wafer WS. The showerhead 6 may include spout holes 7 for spouting the gas G1. A piping line 8 for supplying the gas G1 into the showerhead 6 is provided above the showerhead 6. The gas G1 can develop a plasma etching process inside the chamber 1. Here, the showerhead 6 is configured to serve as an upper electrode in plasma generation. The pedestal 2 is configured to serve as a lower electrode in plasma generation. An exhaust piping line 9 is provided at a lower part of the chamber 1.

The pedestal 2 is equipped with an electrostatic chuck 13 for fixing the sensing wafer WS, at the top. The electrostatic chuck 13 includes a chuck electrode 15 embedded therein, where the chuck electrode 15 can generate an electrostatic force for attracting the sensing wafer WS. Accordingly, the pedestal 2 and the electrostatic chuck 13 serve as a wafer holder for holding the sensing wafer WS, inside the chamber 1 in which plasma is generated.

An uneven surface 14 is provided on the front side of the electrostatic chuck 13. The uneven surface 14 may be formed of an emboss-processed surface. The uneven surface 14 is provided to allow a heat transfer medium supplied to the back side of the sensing wafer WS to be diffused entirely over the back side of the sensing wafer WS. As the heat transfer medium, for example, Helium(He) gas may be used. An opening 1A and a shutter 24 are provided on the lateral side of the chamber 1. The shutter 24 can be slid up and down. The opening 1A is opened and closed by sliding the shutter 24 up and down.

The pedestal 2 and the electrostatic chuck 13 (wafer holder) include through holes 10 and 11 formed therein. The through hole 10 can be used as a passage that allows an incoming light Li emitted from below the pedestal 2 to come in from the back side of the sensing wafer WS, and allows an outgoing light Le emitted from the back side of the sensing wafer WS to go out downward from the pedestal 2. The through hole 10 can also be used as a passage to supply the heat transfer medium to the back side of the sensing wafer SIS. Each through hole 11 is provided with a pin 12 inside. The pin 12 can be moved up and down. The sensing wafer WS can be moved up and down by moving the pins 12 up and down, when the sensing wafer WS is to be transferred.

Further, the plasma etching apparatus is equipped with a high-frequency RF power supply 19, a low-frequency RF power supply 22, and a chucking power supply 23. The low-frequency RF power supply 22 can apply a first frequency voltage to the pedestal 2 in a continuous or pulsed form. The high-frequency RF power supply 19 can apply a second frequency voltage to the pedestal 2 in a continuous or pulsed form. The second frequency may be set higher than the first frequency. For example, the first frequency may be set to 13.56 MHz or less, and the second frequency may be set to 40 MHz or more.

Here, the second frequency voltage can be used to generate high density plasma inside the chamber 1. The first frequency voltage can be used to control ion energy generated inside the chamber 1. The chucking power supply 23 can apply a chucking voltage to the chuck electrode 15. The chucking voltage can be used to perform chucking cif the sensing wafer WS onto the electrostatic chuck 13.

The low-frequency RF power supply 22 is connected to the pedestal 2 through a matching device 21 and a blocking capacitor 20 in this order. The high-frequency RF power supply 19 is connected to the pedestal 2 through a matching device 18 and a blocking capacitor 17 in this order. The chucking power supply 23 is connected to the chuck electrode 15. The blocking capacitors 17 and 20 can block DC current generated by polarization of electric charges in plasma, and thereby generate a self-bias electric potential. The matching device 18 can achieve impedance matching with respect to the load of the high-frequency RF power supply 19. The matching device 21 can achieve impedance matching with respect to the load the low-frequency RF power supply 22.

Further, at the bottom of the chamber 1, an opening 1B and a viewport 25 are provided. The viewport 25 may be made of a transparent material, such as quartz. The viewport 25 may be arranged at the position of the opening 1B. The viewport 25 may be fixed to the chamber 1 by screws 27 through a frame 26 that presses the cuter edge of the viewport 25. In this case, in order to ensure the airtightness inside the chamber 1, an O-ring 26 may be fitted between the viewport 25 and the bottomthe chamber 1.

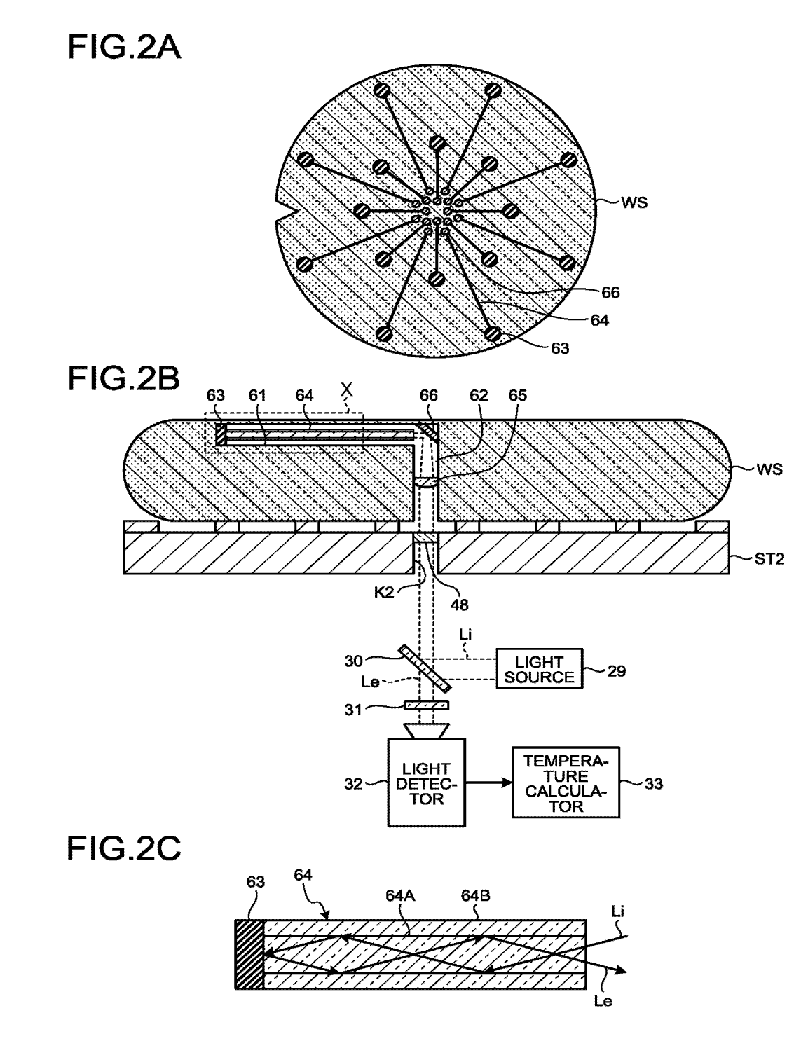

FIG. 2A is a plan view illustrating a schematic configuration of a sensing wafer to be applied to the temperature measuring system according to the firs* embodiment. FIG. 23 is a sectional view illustrating a schematic configuration of the sensing wafer of FIG. 2A. FIG. 2C is a sectional view illustrating a wave-guiding state of an incoming light and an outgoing light inside an optical fiber provided in the sensing wafer of FIG. 2B; and illustrates an enlarged view of portion X in FIG. 2B.

As illustrated in FIG. 28, passages 61 are formed below the front side of the sensing wafer WS. The passages 61 may be arranged to extend from the central portion of the sensing wafer WS toward its end portions. A passage 62 is formed at the central portion of the sensing wafer WS. The passage 62 may penetrate the central portion of the back side of the sensing wafer WS. The distal end of the passage 62 may be coupled with the proximal end of each passage 61.

An excitation light emitter 63 is arranged at the distal end of each passage 61. The excitation light emitter 63 can emit an outgoing light Le on the basis of the incoming light Li. In this case, the outgoing light Le can have a temperature characteristic. The excitation light emitter 63 may be made of a fluorescent substance that generates fluorescence or phosphorescence as the outgoing light Le. As the fluorescent substance, for example, Y₂O₃:Eu(Europium), Mg₄FGeO₆:Mn(Manganum), YAG (Yttrium Aluminum Garnet):Dy (Dysprosium), or YAG:Tb (Terbium) may be used. Further, in place of the excitation light emitter 63, for example, a single-crystalline semiconductor, such as GaAs (Gallium Arsenicum), different in kind from the wafer substrate may be used, such that the single-crystalline semiconductor can generate lattice vibration by irradiation with visible light and has temperature dependence in light absorption wavelength due to the lattice vibration.

Further, in each passage 61, an optical fiber 64 is provided to extend from the excitation light emitter 63 to the passage 62. As illustrated in FIG. 2C, the optical fiber 64 includes a core 64A and a clad 64B. As the optical fiber 64, a high heat resistant optical fiber based on quartz is preferably used. The high heat resistant optical fiber can withstand a high temperature of 1,000° C. or more.

Reflecting mirrors are arranged at the distal end of the passage 62. Further, a collimation lens 65 is provided in the passage 62. As he material of the collimation lens 65, for example, quartz may be used. The collimation lens 65 ay be arranged below the reflecting mirrors 66.

Here, as illustrated in FIG. 2A, the excitation light emitters 63 may be provided at a plurality of places of the sensing wafer WS. The optical fibers 64 and the reflecting mirrors 66 may be arranged in the sensing wafer WS to correspond to the respective excitation light emitters 63 provided at a plurality of places. The excitation light emitters 63 are preferably arranged at almost regular intervals in the sensing wafer WS. The optical fibers 64 may be radially arranged from the central portion of the sensing wafer WS toward its end portions. The length of the optical fibers 64 can be adjusted in accordance the positions of the excitation light emitters 63. In this case, the optical fibers 64 may have different lengths.

Further, as illustrated in FIG. 22, a stage ST2 is provided inside the chamber. The sensing wafer WS can be placed on the stage ST2. The stage ST2 may be the pedestal 2 of FIG. 1, or may be the electrostatic chuck 13 of FIG. 1. The stage ST2 can be used as a wafer holder for holding the wafer W or sensing wafer WS inside the chamber 1.

At the central portion of the stage ST2, an opening K2 is formed to penetrate the stage ST2 in the thickness direction. The opening K2 is provided with a transmission window 48 on the front side, which transmits the incoming light Li and the outgoing light Le. As the transmission window 48, transparant and heat conductive materials, for example, AlN or AlON may be used.

Below the stage ST2, a light source 29, a half mirror 30, a light-filter 31, a light detector 32, and a temperature calculator 33 are provided. The light source 29 generates an incoming light Li to be incident onto the excitation light emitters 63. The half mirror 30 reflects the incoming light Li, and transmits the outgoing light Le. The light-filter 31 transmits a wavelength component of the outgoing light Le, and attenuates the other wavelength components. For example, where the incoming light Li is blue light and the outgoing light Le is red light, a red filter may be used as the light-filter 31. The light detector 32 detects the outgoing light Le. The temperature calculator 33 calculates the temperature of the sensing wafer WS on the basis of a temperature characteristic of the outgoing light Le.

The light rce 29, the half mirror 30, the light-filter 31, the light detector 32, and the temperature calculator 33 may be arranged outside the chamber 1 of FIG. 1. Alternatively, the light source 29, the half mirror 30, the light-filter 31, the light detector 32, and the temperature calculator 33 may be arranged inside the chamber 1 of FIG. 1. In this case, the light source 29, the half mirror 30, the light-filter 31, the light detector 32, and the temperature calculator 33 may be arranged below the pedestal 2 of FIG. 1. In this case, there is no need to provide the chamber 1 with the opening 1B and the viewpor FIG. 1.

Next, an explanation will be given of a method of measuring a temperature during a plasma process inside the chamber by using the sensing wafer WS.

With reference to FIGS. 1, 2A, and 2B, when the sensing wafer WS is to be transferred into the chamber 1, the shutter 24 is opened and the pins 12 are projected upward from the electrostatic chuck 13. Then, the sensing wafer WS is transferred through the opening 1A onto the pins 12. Then, the pins 12 are moved down in a state where the sensing wafer WS is placed on the pins 12, and the sensing wafer WS is thereby placed onto the electrostatic chuck 13. Then, the sensing wafer WS is attracted by the electrostatic chuck 13, and thus the sensing wafer WS is fixed on the electrostatic chuck 13.

Further, a heat transfer medium is supplied to the back side of the sensing wafer WS, and is diffused entirely over the back side of the sensing wafer WS through the uneven surface 14, to control the temperature of the sensing wafer WS. Then, while the inside of the chamber 1 is exhausted through the exhaust piping line 9, a gas G1 is spouted from the showerhead 6. Then, the second frequency voltage is supplied from the high-frequency RF power supply 19 to the pedestal 2, and the gas G1 is thereby excited to generate plasma above the sensing wafer WS.

At this time, the first frequency voltage is applied in a continuous or pulsed form from the low-frequency RF power supply 22 to the pedestal 2, to control the energy for attracting ions generated inside the chamber 1 to the sensing wafer WS. Then, ions generated above the sensing wafer WS cause sputtering the sensing wafer WS and/or an ion-assisted reaction on the sensing wafer WS, whereby a plasma etching process is performed.

During the plasma etching process, an incoming light Li is emitted from the light source 29. Then, the incoming light Li is reflected by the half mirror 30, and is then transmitted through the transmission window 48 and the collimation lens 65. Further, the incoming light Li is reflected by the respective reflecting mirrors 66, and then comes into the respective optical fibers 64. As illustrated in FIG. 2C, the incoming light Li is guided by the optical fibers 64, and is incident onto the respective excitation light emitters 63.

At each excitation light emitter 63, an outgoing light Le is generated in response to the incidence of the incoming light Li, and comes into the corresponding optical fiber 64. The respective outgoing lights Le are guided by the optical fibers 64, and are reflected by the respective reflecting mirrors 66. Further, the outgoing lights Le are condensed by the collimation lens 65 as a condensed outgoing light Le, which is then transmitted through the transmission window 48, and goes out from the back side of the stage ST2. The outgoing light Le going out from the back side of the stage ST2 is transmitted through the half mirror 30, and a desired wavelength component is extracted therefrom by the light-filter 31, and is incident onto the light detector 32, by which the outgoing light Le is detected. The detection result obtained by the light detector 32 is sent to the temperature calculator 33. Upon reception of the detection result from the light detector 32, the temperature calculator 33 calculates the temperature of the sensing wafer WS on the basis of a temperature characteristic of the outgoing light Le. The temperature characteristic of the outgoing light Le may be temperature dependence in the decay time of the outgoing light Le, may have temperature dependency in the wavelength of the outgoing light Le, or may have temperature dependency in the wavelength peak intensity ratio of the outgoing light Le.

Here, the respective outgoing lights Le emitted from the plurality of excitation light emitters 63 can be guided into one passage 62. Then, the respective outgoing lights Le emitted from the plurality of excitation light emitters 63 can be made incident all together onto the light detector 32, for example. In this case, the temperature calculator 33 can calculate the average of the temperatures of a plurality of measurement points of the sensing wafer WS on the basis of the detection results sent from the light detector 32. Alternatively, an optical system used for the plurality of excitation light emitters 63 may be structured such that the respective outgoing lights Le emitted from the excitation light emitters 63 are individually guided to light detectors 32. In this case, the temperatures of the respective measurement points of the sensing wafer WS may be calculated on the basis of the respective outgoing lights Le emitted from the excitation light emitters 63.

Here, as the temperature measurement is performed on the basis of a temperature characteristic of the outgoing light Le, an electric wire for sending temperature measurement values outside the chamber 1 is not required any more to extend through inside the chamber 1. Accordingly, it is possible to measure a temperature inside the chamber 1 without opening the chamber 1 to the atmosphere, and thus to manage the temperature inside the chamber 1 even during a plasma process.

Further, as the temperature measurement is performed on the basis of a temperature characteristic of the outgoing light Le, it is possible to improve the temperature resolution as compared with a method using a thermo-label, and thus to improve the temperature measurement accuracy during a plasma process.

Further, as the temperature measurement is performed on the basis of a temperature characteristic of the outgoing light Le, it is possible to improve the heat resistance and electromagnetic noise resistance. This makes it possible to apply this method to temperature measurement during a plasma process with a high frequency and a high power, while suppressing deterioration of the service life of the sensing wafer WS.

Further, as the excitation light emitters 63 and the optical fibers 64 are provided in the sensing wafer WS, it is possible to measure a temperature under conditions equivalent to conditions for processing the wafer W for forming devices. This makes it possible to measure by the sensing wafer WS a temperature equivalent to the temperature of processing points on the wafer W for forming devices, and thus to improve the processing accuracy on the wafer W for forming devices.

Further, as the excitation light emitters 63 and the optical fibers 64 are provided in the sensing wafer WS, it is possible to easily increase the number of temperature measurement points, and thus to improve the temperature management accuracy inside the chamber 1 during a plasma process, while suppressing the cost increase.

Further, as the passage 62 is formed in the sensing wafer WS, it is possible to allow the incoming light Li to come in from the back side of the sensing wafer WS and to allow the outgoing light Le to go out from the back side. This makes it possible to prevent the incoming light Li and the outgoing light Le from being exposed to plasma during a plasma etching process, and thus to prevent generation of temperature measurement errors due to the light emission from plasma.

Further, as the incoming light Li is caused to come in from the back side of the sensing wafer WS and the outgoing light Le is caused to go out from the back side, it is possible to prevent the transmission window 46 and the collimation lens 65 from being exposed to plasma. This makes it possible to prevent the transmission window 46 and the collimation lens 65 from being clouded or damaged by the plasma, and thus to prevent deterioration of the temperature measurement accuracy.

Further, as the incoming light Li is caused to come in from the back side of the sensing wafer WS and the outgoing light Le is caused to go out from the back side, it is possible to set the light source 29 and the light detector 32 to be closer to the stage ST2, without depending on the size of the chamber in the lateral direction. This makes it possible to shorten the path length of the incoming light Li from the light source 29 to the sensing wafer WS and the path length of the outgoing light Le from the light detector 32 to the sensing wafer WS, and thus to facilitate adjustment of the positions of the light source 29 and the light detector 32.

It should be noted that, in the embodiment described above, the semiconductor manufacturing apparatus is exemplified by a plasma etching apparatus of the capacitive coupling type, the apparatus may be a plasma etching apparatus of the inductively coupled type, or may be a plasma etching apparatus of the microwave ECR (Electron Cyclotron Resonance) type. Further, the semiconductor manufacturing apparatus may be a plasma CVD (Chemical Vapor Deposition) apparatus, or may be applied to an epitaxial apparatus, thermal CVD apparatus, or anneal apparatus, other than the plasma processing apparatus.

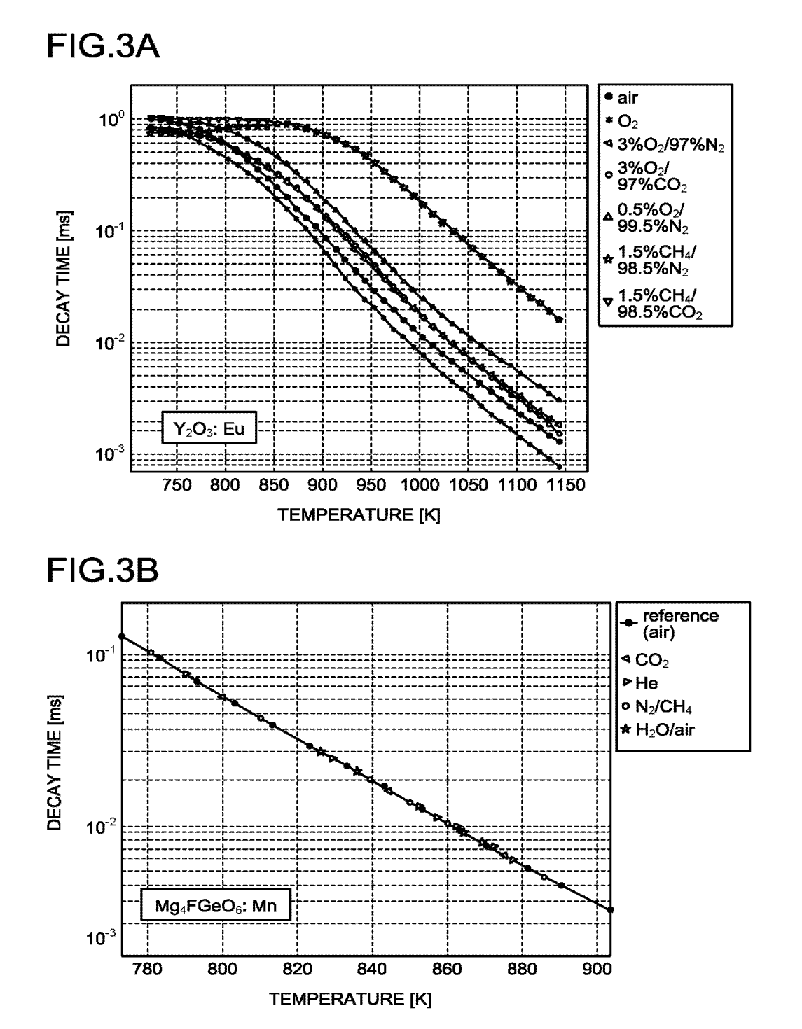

Next, a specific explanation will be given of the principle of temperature measurement based on a temperature characteristic of the outgoing light Le. FIGS. 3A and are graphs illustrating the relationship between the temperature and phosphorescence decay time of a fluorescent substance used as an excitation light emitter in the temperature measuring system of FIG. 1. For example, this relationship is described in “Brubach, J.; Dreizler, A.; Janica, J., “Gas compositional and pressure effects on thermographic phosphor thermometry”, Measurement Science Technology 2007, 18, 76-770”. Here, FIG. 3A takes Y₂O₃:Eu as an example of the fluorescent substance, and FIG. 3B takes Mg₄FGeO₆:Mn as an example of the fluorescent substance. Further, FIGS. 3A and 3B illustrate the relationship between the temperature and phosphorescence decay time of a fluorescent substance obtained when the atmosphere around the fluorescent substance is varied.

As illustrated in FIGS. 3A and 3B, it is understandable that the phosphorescence decay time has temperature dependence. Accordingly, by measuring the phosphorescence decay time, the temperature of the sensing wafer WS provided with the fluorescent substance can be calculated.

However, in the case of Y₂O₃:Eu, the phosphorescence decay time depends on the atmosphere around the fluorescent substance. On the other hand, in the case of Mg₄FGeO₆:Mn, the phosphorescence decay time does not depend on the atmosphere around the fluorescent substance. Accordingly, when Y₂O₃:Eu is used as the fluorescent substance, the fluorescent substance is preferably sealed. On the other hand, when Mg₄FGeO₆:Mn is used as the fluorescent substance, temperature measurement can be performed with high accuracy even where the fluorescent substance is not sealed.

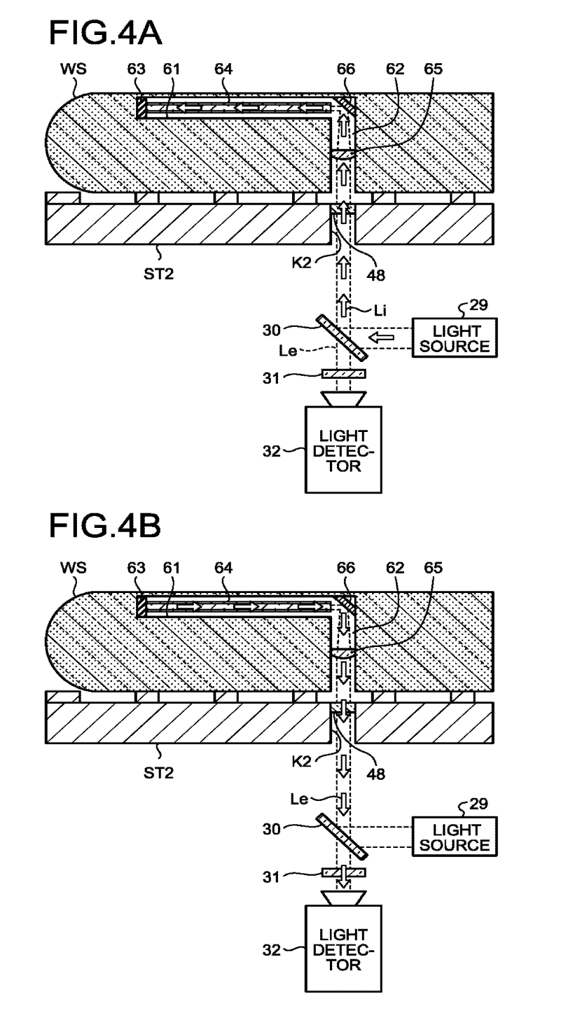

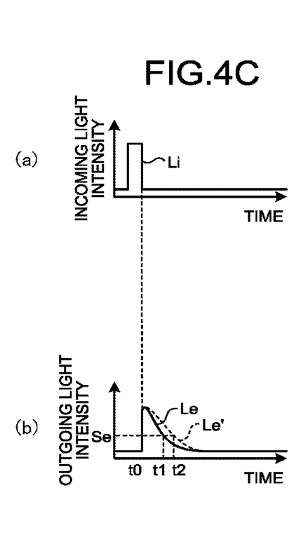

FIG. 4A a sectional view illustrating a state of the incoming light coming into the sensing wafer. FIG. 4B is a sectional view illustrating a state of the outgoing light going out from the sensing wafer. FIG. 4C illustrates the waveforms of the incoming light to the sensing wafer and the outgoing light from the sensing wafer. Here, FIGS. 4A to 4C illustrate an example where temperature measurement is performed by using temperature dependence in the decay time of the outgoing light Le.

During a plasma etching process, as illustrated in (a) of FIG. 4C, an incoming light Li is emitted in a pulsed form from the light source 29 of FIG. 4A. Then, as illustrated in FIG. 4A, the incoming light Li is reflected by the half mirror 30, and is then transmitted through the transmission window 48 and the collimation lens 65. Further, the incoming light Li is reflected by the respective reflecting mirrors 66, and then comes into the respective optical fibers 64. The incoming light Li is guided by the optical fibers 64, and is propagated to the respective excitation light emitters 63.

At each excitation light emitter 63, as illustrated in FIG. 48 and (b) of FIG. 4C, an outgoing light Le is generated in response to the incidence of the incoming light Li, and comes into the corresponding optical fiber 64. The respective outgoing lights Le are guided by the optical fibers 64, and are reflected by the respective reflecting mirrors 66. Further, the outgoing lights Le are condensed by the collimation lens 65 as a condensed outgoing light Le, which is then transmitted through the transmission window 48, and goes out from the back side of the stage ST2. The outgoing light Le going out from the back side of the stage ST2 passes through the half mirror 30 and the light-filter 31, and is incident onto the light detector 32, by which the outgoing light Le is detected. The detection result obtained by the light detector 32 is sent to the temperature calculator 33. The temperature calculator 33 measures, for example, the time since the falling time point t0 of the incoming light Li until the intensity of the outgoing light Le becomes Se.

At this time, as illustrated in FIGS. 3A and as the temperature is higher, the phosphorescence decay time becomes shorter. Thus, the waveform of the outgoing light becomes Le at a high temperature, and the waveform of the outgoing light becomes Le′ at a low temperature. It is understandable that, when the decay time until the intensity of the outgoing light Le becomes Se is “t1-t0”, the sensing wafer WS is in a high temperature state; and, when the decay time until the intensity of the outgoing light Le′ becomes Se is “t2-t0”, the sensing wafer WS is in a low temperature state. The temperature value of the sensing wafer WS in the high temperature state or low temperature state can be obtained with reference to FIG. 3A or FIG. 3B.

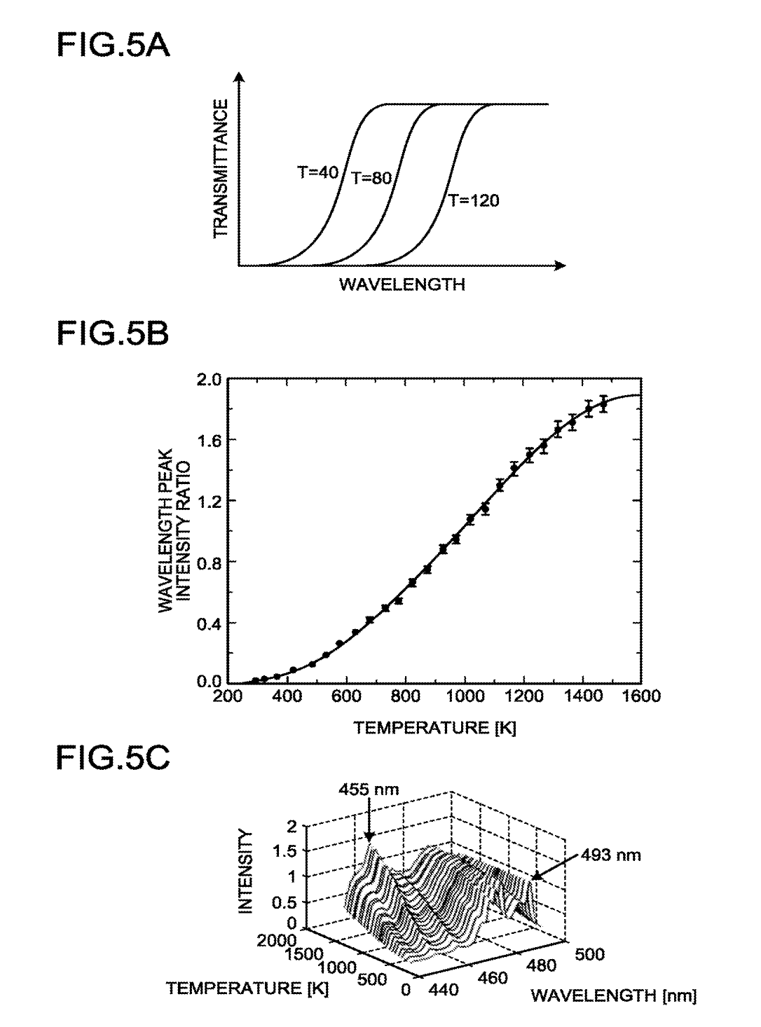

FIG. 5A is a graph illustrating the relationship between the temperature and wavelength of a single-crystalline semiconductor used in the temperature measuring system of FIG. 1. FIG. 5B is a graph illustrating the relationship between the temperature and wavelength peak intensity ratio of a fluorescent substance used as an excitation light emitter in the temperature measuring system of FIG. 1. FIG. 5C is a graph illustrating the relationship between the temperature, wavelength, and intensity of the fluorescent substance used as an excitation light emitter in the temperature measuring system of FIG. 1. For example, the relationships of FIGS. 5B and 5C are described in “M Yu, et. al., “Survivability of thermographic phosphors (YAG:Dy) in a combustion environment”, Meas. Sci. Technol. 21 (2010)”.

Here, FIG. 5A takes GaAs as an example of the single-crystalline semiconductor, and FIGS. 5B and 5C take YAG:Dv as an example of the fluorescent substance.

As illustrated in FIG. 5A, it is understandable that the transmission wavelength of the single-crystalline semiconductor irradiated with, for example, white light has temperature dependence. Accordingly, by measuring the transmission wavelength of the single-crystalline semiconductor, the temperature of the sensing wafer WS provided with the single-crystalline semiconductor as a temperature measuring element can be measured.

On the other hand, as illustrated in FIG. 5C, it is understandable that phosphorescence emitted from YAG:Dy has a peak at 455 nm and at 493 nm. In this case, as illustrated in FIG. 5B, it is understandable that the ratio between the intensity at 455 nm and the intensity at 493 nm has temperature dependence. Accordingly, by measuring the wavelength peak intensity ratio of the fluorescent substance, the temperature of the sensing wafer WS provided with the fluorescent substance can be measured.

Here, there is a structure in which the excitation light emitters 63 are provided at a plurality of places of the sensing wafer WS, and the reflecting mirrors 66 are arranged in a two-dimensional state at the central portion of the sensing wafer WS to correspond to the respective excitation light emitters 63, such that the incoming lights Li and the outgoing lights Le can be individually guided for the respective excitation light emitters 63, to measure the temperatures of a plurality of places of the sensing wafer WS. In this structure, some outgoing lights Le reflected by reflecting mirrors 66 adjacent to each other may cause interference among them.

Next, an explanation will be given of a method for preventing the interference among outgoing lights Le reflected by reflecting mirrors 66, even where the excitation light emitters 63 are provided at a plurality of places of the sensing wafer WS d the intervals of the reflecting mirrors 66 are small.

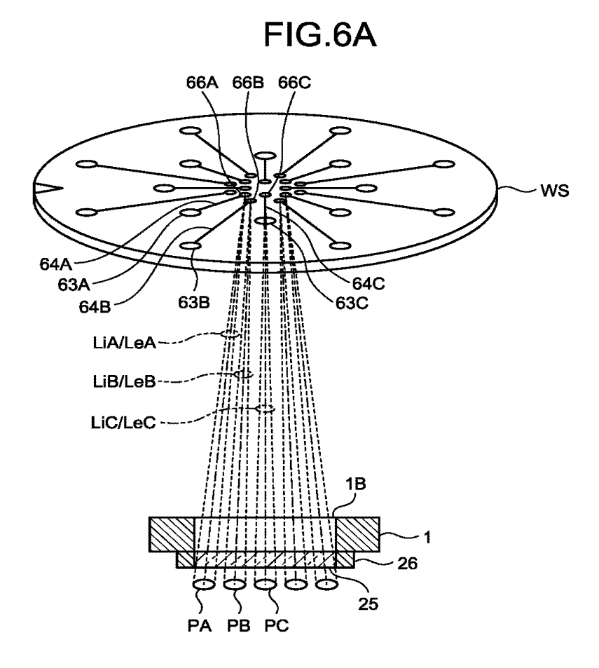

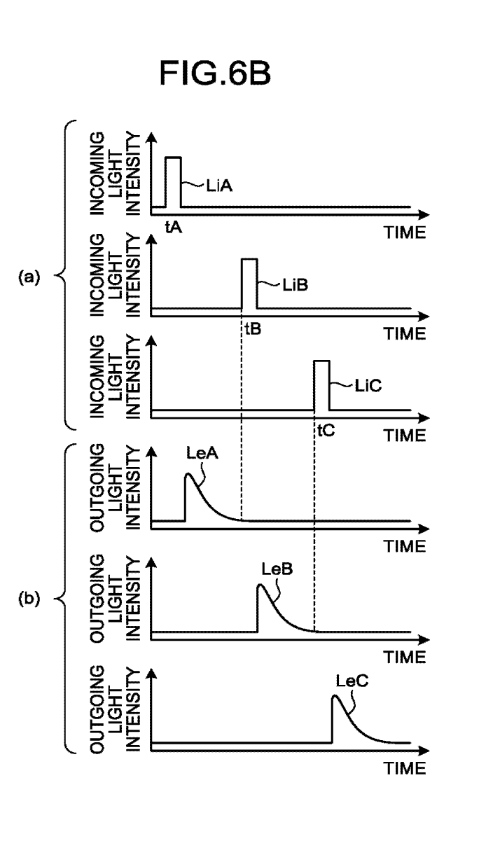

FIG. 6A is a perspective view illustrating the incoming paths of incoming lights and the outgoing paths of outgoing lights in a case where a plurality of temperature measurement points are present on the sensing wafer. FIG. 6B illustrates the waveforms of the incoming lights at the respective temperature measurement points and the waveforms of the outgoing lights from the respective temperature measurement points in the case where a plurality of temperature measurement points are present on the sensing wafer.

As illustrated in FIG. 6A, for example, it is assumed that reflecting mirrors 66A to 66C are arrange adjacent to each other at the central portion of the sensing wafer WS. Optical fibers 64A to 64C are provided in the sensing wafer WS to correspond to the reflecting mirrors 66A to 66C, respectively. At the distal ends of the optical fibers 64A to 64C, the excitation light emitters 63A to 63C are arranged, respectively.

Respective incoming lights LiA to LiC vertically coming into the back side of the sensing wafer WS are reflected by the reflecting mirrors 66A to 66C in the horizontal direction, and come into the optical fibers 64A to 64C, respectively. Respective outgoing lights LeA to LeC guided by the optical fibers 64A to 64C in the horizontal direction are reflected by the reflecting mirrors 66A to 66C in the vertical direction, and go out from the back side of the sensing wafer WS. Here, it is assumed that detection points PA to PC are arranged at positions where the respective outgoing lights LeA to LeC can interfere with each other because of the spreads of the respective outgoing lights LeA to LeC.

At this ime, the respective incoming lights LiA to LiC can be set to come into the optical fibers 64A to 64C with timing shifted among the respective incoming lights LiA to LiC. Specifically, as illustrated in (a) of FIG. 68, at a time point tA, the incoming light LiA is made incident in a pulsed form onto the excitation light emitter 63A through the optical fiber 64A. At this time, as illustrated in (b) of FIG. 68, the outgoing light LeA is emitted from the excitation light emitter 63A.

Then, as illustrated in (a) of FIG. 68, at a time point tB when the outgoing light LeA emitted from the excitation light emitter 63A has sufficiently decayed, the incoming light LiB is made incident in a pulsed form onto the excitation light emitter 63B through the optical fiber 64B. At this time, as illustrated in (b) of FIG. 6B, the outgoing light. LeB is emitted from the excitation light emitter 63B.

Then, as illustrated in (a) of FIG. 6B8, at a time point tC when the outgoing light LeB emitted from the excitation light emitter 63B has sufficiently decayed, the incoming light LiC is made incident in a pulsed form onto the excitation light emitter 63C through the optical fiber 64C. At this time, as illustrated in (b) of FIG. 6B, the outgoing light LeC is emitted from the excitation light emitter 63C.

Consequently, even if the detection points PA to PC are arranged at positions where the respective outgoing lights LeA to LeC can interfere with each other, the outgoing lights LeA to LeC can be detected by the detection points PA to PC, without causing interference among the outgoing lights LeA to LeC. Thus, even where a plurality of temperature measurement points are present on the sensing wafer WS, it is possible to improve the temperature measurement accuracy, while preventing increase in the size of the viewport 25.

### Second Embodiment

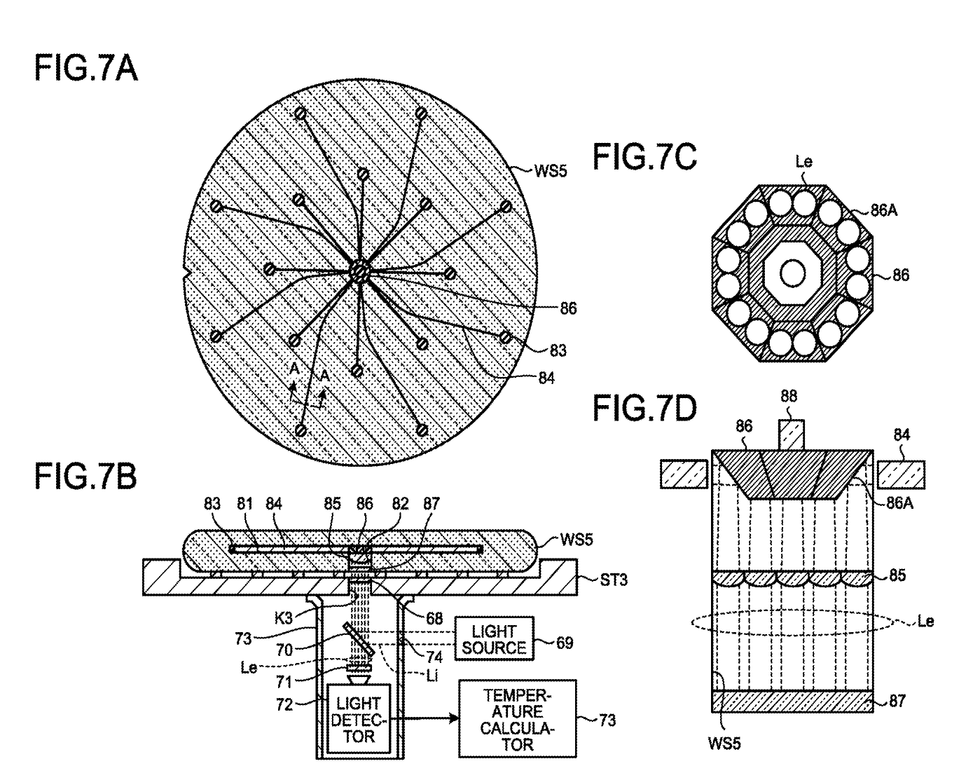

FIG. 7A is a plan view illustrating a schematic configuration of a sensing wafer to be applied to a temperature measuring system according to a second embodiment. FIG. 7B is a sectional view illustrating a schematic configuration of the temperature measuring system according to the second embodiment. FIG. 7C is a plan view illustrating a schematic configuration of an optical system at the midmost part of the sensing wafer of FIG. 7B. FIG. 7B is a sectional view illustrating a schematic configuration of the optical system at the midmost part of the sensing wafer of FIG. 7B.

As illustrated in FIG. 7B, passages 81 are formed below the front side of the sensing wafer WS5. The passages 81 may be arrange to extend from the central portion of the sensing wafer 55 toward its end portions. A passage 82 is formed at the central portion of the sensing wafer WS5. The passage 82 may penetrate the central portion of the back side of the sensing wafer WS5. The distal end of the passage 82 may be coupled with the proximal end of each passage 81.

An excitation light emitter 83 is arranged at the distal end of each passage 81. The excitation light emitter 83 may be configured as in the excitation light emitter 63 of FIG. 2A. Further, in each passage 81, an optical fiber 84 is provided to extend from the excitation light emitter 83 to the passage 82.

Here, as illustrated in FIG. 7A, the excitation light emitters 83 are provided at a plurality of places of the sensing wafer WS5. The optical fibers 84 are arranged in the sensing wafer WS5 to correspond to the respective excitation light emitters 83 provided at a plurality of places. In this case, the optical fibers 84 may be radially arranged from the central portion of the sensing wafer WS5 toward its end portions.

A reflecting mirror 86 is arranged at the distal end of the passage 82. In this case, the reflecting mirror 86 may be arranged at the central portion of the sensing wafer WS5. As illustrated in FIGS. 7C and 7D, the reflecting mirror 86 includes a plurality of reflecting surfaces 86A. Here, the orientations of the respective reflecting surfaces 86A may be set to face the end surfaces of the optical fibers 84, each in a state inclined by 45° relative to the corresponding end surface. In this case, a plurality of outgoing lights Le guided through the respective optical fibers 84 in various directions can be simultaneously reflected by the reflecting mirror 26 in the same direction. Here, an optical fiber 88 may be provided at the center of the reflecting mirror 86 to penetrate the reflecting mirror 86.

Further, a plurality of collimation lenses 85 and a transmission window 87 are arranged in the passage 82. The collimation lenses 85 may be arranged below the reflecting mirror 86, and the transmission window 87 may be arranged below the collimation lenses 25. As the material of the transmission window 87, for example, AlN or AlON may he used.

Further, as illustrated in FIG. 7B, a stage ST3 is provided inside the chamber. The sensing wafer WS5 can he placed on the stage ST3. The stage ST3 may be the pedestal 2 of FIG. 1, or may be the electrostatic chuck 13 of FIG. 1.

At the central portion of the stage ST3, an opening K3 is formed to penetrate the stage ST3 in the thickness direction. The opening K3 is provided with a transmission window 68 on the front side. As the material of the transmission window 68, for example, AlN or AlON may be used.

A cylindrical body 73 is attached below the stage ST3. The distal end of the cylindrical body 73 may be fixed to the back side of the stage ST3. The cylindrical body 73 is provided with a transmission window 74 on the lateral side. Inside the cylindrical body 73, a half mirror 70, a light-filter 71, and a light detector 72 are provided. Outside the cylindrical body 73, a light source 69 and a temperature calculator 73 are provided. The single light source 69 and the single light detector 72 can be used for the plurality of outgoing lights Le in common.

The light source 69 generates an incoming light Li to be incident onto the excitation light emitters 83. The half mirror 70 reflects the incoming light Li, and transmits the outgoing lights Le. The light-filter 71 transmits a wavelength component of the outgoing lights Le, and attenuates the other wavelength components. The light detector 72 detects the outgoing lights Le. Here, the light detector 72 can simultaneously detect the plurality of outgoing lights Le. In order to simultaneously detect the plurality of outgoing lights Le, an image sensor, such as a CCD or CMOS sensor, may be used as the light detector 72. The temperature calculator 73 calculates the temperature of the sensing wafer WS5 on the basis of a temperature characteristic of the outgoing lights Le.

Next, an explanation will be given of a method of measuring a temperature during a plasma process inside the chamber by using the sensing wafer WS5.

With reference to FIG. 7B, the sensing wafer WS5 is transferred into the chamber, and the sensing wafer is placed on the stage ST3.

Then, during the plasma etching process, an incoming light Li is emitted from the light source 60. Then, the incoming light Li is transmitted through the transmission window 74 and reflected by the half mirror 70, and is then transmitted through the transmission windows 68 and 87 and the collimation lenses 85. Further, the incoming light Li is reflected by the reflecting mirror 86 in radial directions, and then comes into the plurality of optical fibers 84. The incoming light Li is guided by the plurality of optical fibers 84, and is incident onto the plurality of excitation light emitters 83.

At each excitation light emitter 83, an outgoing light Le is generated in response to the incidence of the incoming light Li, and comes into the corresponding optical fiber 84. The respective outgoing lights Le are guided by the optical fibers 84, and are reflected by the respective reflecting surfaces 86A of the reflecting mirror 86. Further, the plurality of outgoing lights Le are individually condensed by the plurality of collimation lenses 85, are then transmitted through the transmission windows 87 and 68, and go out from the back side of the stage ST3.

The plurality of outgoing lights Le going out from the back side of the stage ST3 are transmitted through the half mirror 70, and a desired wavelength component is extracted therefrom by the light-filter 71, and is incident onto the light detector 72, by which the plurality of outgoing lights Le are detected. The detection result obtained by the light detector 72 is sent to the temperature calculator 73. Upon reception of the detection result from the light detector 72, the temperature calculator 73 calculates the temperatures of a plurality of measurement points of the sensing wafer WS5 on the basis of a temperature characteristic of the plurality of outgoing lights Le.

Here, as the reflecting mirror 86 including the plurality of reflecting surfaces 86A is arranged at the central portion of the sensing wafer WS5, the incoming light Li can be made simultaneously incident onto the plurality of excitation light emitters 83 from the back side of the sensing wafer WS5, and the plurality of outgoing lights Le can be simultaneously emitted from the back side. Accordingly, the light source 69 and the light detector 72 can be used for the plurality of excitation light emitters 83 in common. This makes it possible to make the apparatus configuration more compact, as compared with a case where the light source 69 and the light detector 72 are provided with respect to each of the plurality of excitation light emitters 83.

### Third Embodiment

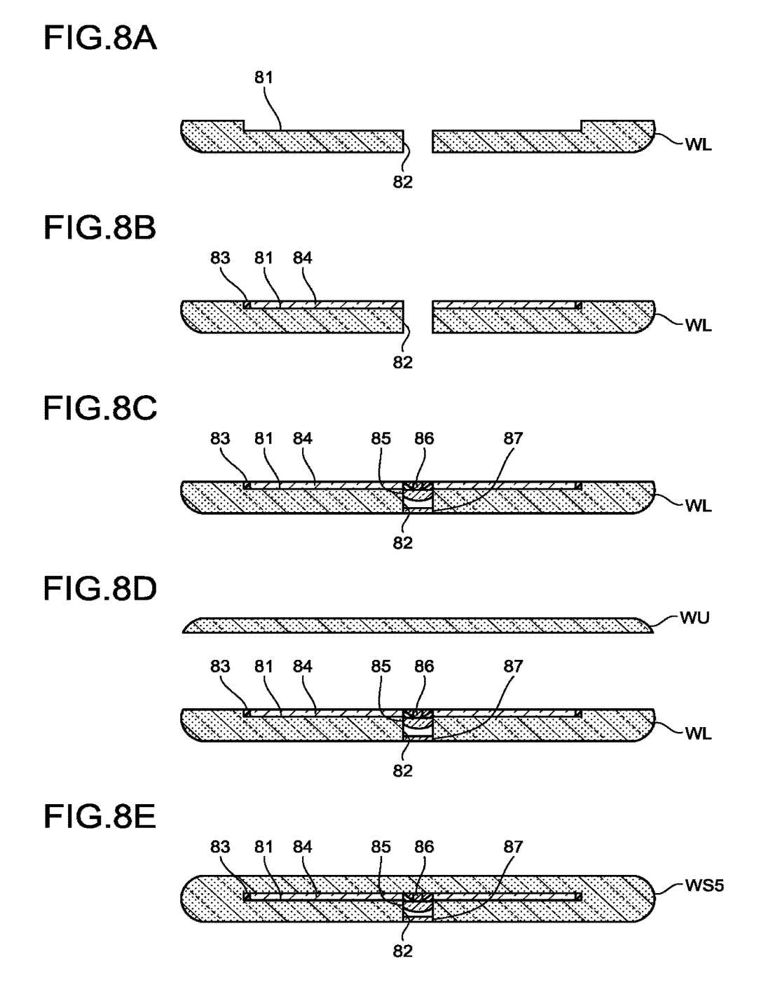

FIGS. 8A to 8E are sectional views illustrating a method of manufacturing a sensing wafer according to a third embodiment. Here, FIGS. 8A to 8E take a method of manufacturing the sensing wafer WS5 of FIG. 7B as an example.

As illustrated in FIG. 8A, by using a photolithography technique and an etching technique, the passage 82 and the passages 81 are formed in a lower wafer WL such that the passage 82 is at the central portion and the passages 81 extend from the central portion in directions toward end portions.

Then, as illustrated in FIG. 8B, the excitation light emitter 83 is provided at the distal end of each passage 81. Further, in each passage 81, the optical fiber 84 is provided to extend from the excitation light emitter 83 to the passage 82.

Then, as illustrated in FIG. 8C, the transmission window 87, the collimation lenses 85, and the reflecting mirror 86 are provided in this order from below in the passage 82.

Then, as illustrated in FIG. 8D, an upper wafer WU is bonded to the upper side of the lower wafer WL. As a result, as illustrated in FIG. 8E, the excitation light emitters 83 and the optical fibers 84 are provided inside the sensing wafer WS5. The lower wafer WL and the upper wafer WU can be used as the wafer substrate of the sensing wafer WS5.

Here, when the lower wafer WL and the upper wafer WU are to be bonded to each other, a ceramic-based adhesive may be used, or wafer direct bonding may be used. By a method using the ceramic-based adhesive or wafer direct bonding, a heat resistance of 1,000° C. or more can be obtained. Where the wafer direct bonding is used, the bonding surfaces may be subjected to a plasma activation process before the bonding. By performing the plasma activation process before the wafer direct bonding, a sufficient bonding strength can be obtained by an anneal process of 200° C. to 300° C.

If the upper wafer WU is contaminated or the upper wafer WU is damaged by temperature measurement during a plasma process, the upper wafer WU can be peeled off the lower wafer WL. Then, a new upper wafer WU can be bonded to the lower wafer WL. At this time, the excitation light emitters 83, the optical fibers 84, the transmission window 87, the collimation lenses 85, and the reflecting mirror 86, which are arranged on the lower wafer WL, can be used again as they are. Consequently, it is possible to reduce the running cost for temperature measurement using the sensing wafer WS5.

### Fourth Embodiment

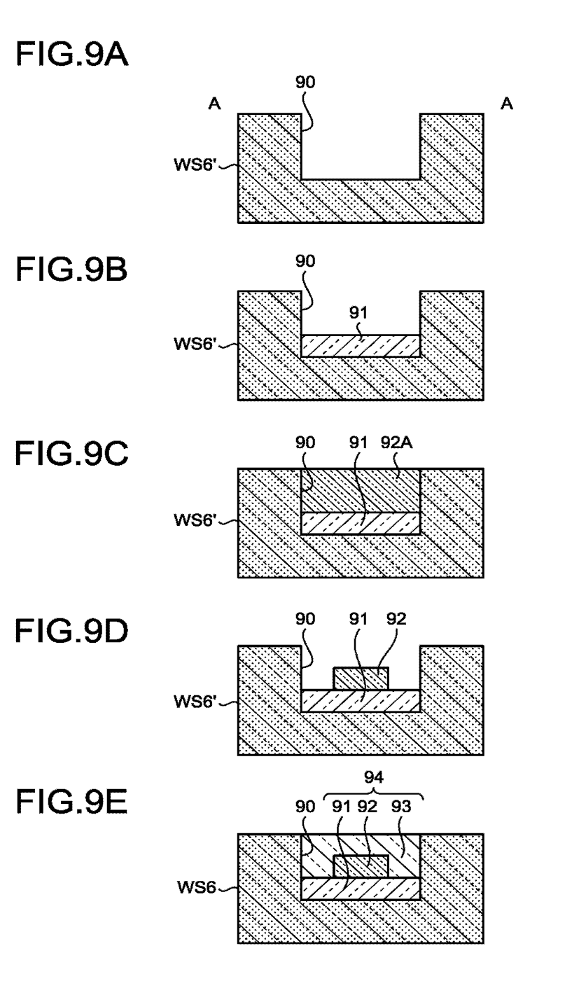

FIGS. 9A to 9E are sectional views illustrating a method of manufacturing a sensing wafer according to a fourth embodiment. Here, FIGS. 9A to 9E illustrate sectional views at a position taken along a line A-A of FIG. 7A.

As illustrated in FIG. 9A, by using a photolithography technique nd an etching technique, trenches 90 are formed in a wafer substrate WS6′ to extend from the central portion in directions toward end portions.

Then, as illustrated in FIG. 9B, a clad material is deposited on the wafer substrate WS6′ by a CVD method or the like such that the clad material is embedded in each trench 90. Then, the clad material is etched back, and a clad layer 91 is thereby formed at the lower side inside each trench 90.

Then, as illustrated in FIG. 9C, a core material 92A is deposited by a CVD method or the like such that the core material 92A is embedded on the clad layer 91 in each trench 90. Then, the core material 92A is planarized by a CMP (Chemical Mechanical Polishing) method or the like.

Then, as illustrated in FIG. 9E, by using a photolithography technique and an etching technique, the core material 92A is patterned such that a core layer 92 is formed at the central portion of each trench 90.

Then, as illustrated in FIG. 9E, a clad layer 93 is deposited on the clad layer 91 by a CVD method or the like such that the core layer 92 is covered with the clad layer 93. Then, the clad layer 93 is planarized by a CMP method or the like. As a result, waveguides 94, each of which includes the core layer 92 covered with the clad layers 91 and 93, are formed in a sensing wafer WS6.

Here, in the case of the sensing wafer WS6, the plurality of waveguides 94 corresponding to the plurality of excitation light emitters 83 can be formed all together. Accordingly, even where the plurality of excitation light emitters 83 are provided in the sensing wafer WS6, it is possible to save the labor for arranging a plurality of optical fibers one by one on the wafer.

In the embodiments described above, an explanation has been given of a method of measuring a temperature by using a sensing wafer provided with an optical fiber and an optical system. A sensing wafer provided with an optical fiber and an optical system can be used for measurement other than the temperature measurement. In this case, the sensing wafer can detect a state inside the sensing wafer or outside the sensing wafer. The state outside the sensing wafer may be a state above the sensing wafer, or may be a state at a lateral side of the sensing wafer.

Next, an explanation will be given of a method of using a sensing wafer provided with an optical fiber and an optical system in measurement or monitoring other than the temperature measurement. The following description will take as an example a configuration in which a sensing wafer is provided with the passages 81 and 82, the optical fibers 84, the reflecting mirror 86, the collimation lenses 85, and the transmission window 87, as illustrated in FIG. 7B.

### Fifth Embodiment

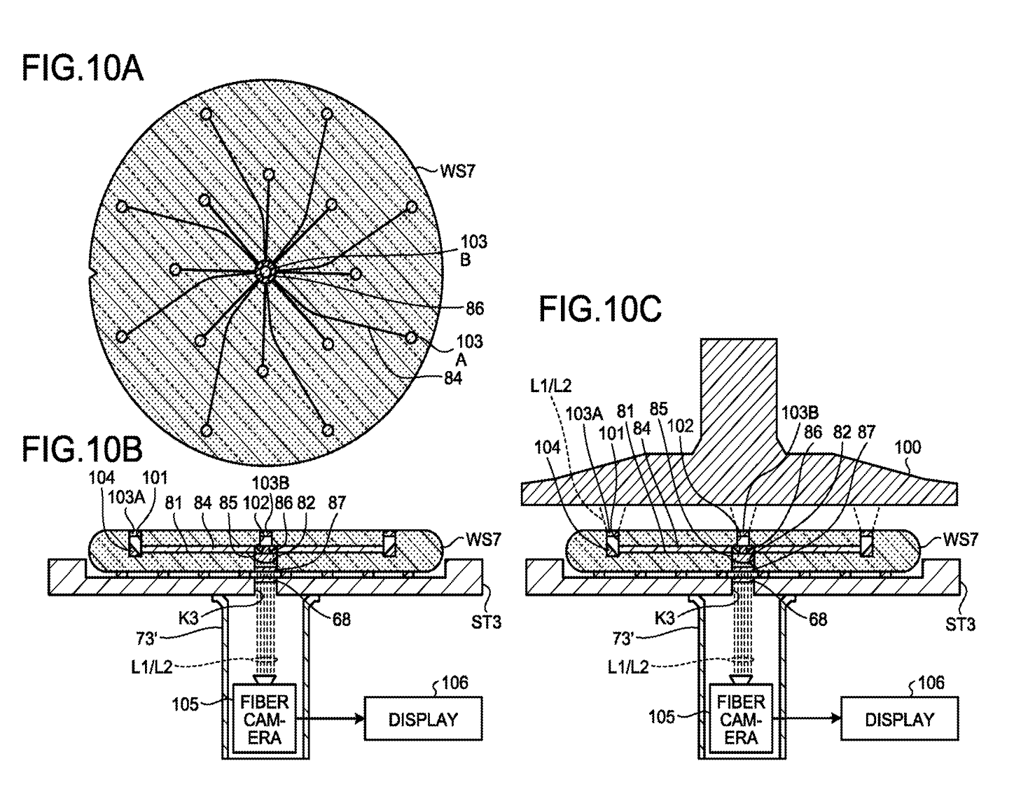

FIG. 10A is a plan view illustrating a schematic configuration of a sensing wafer to be applied to a sensing system according to a fifth embodiment. FIG. 10B is a sectional view illustrating a schematic configuration of the sensing system according to the fifth embodiment. FIG. 10C is a sectional view illustrating an application example of the sensing system according to the fifth embodiment.

As illustrated in FIG. 10B, passages 81 are formed below the front side of the sensing wafer WS7. A passage 82 is formed at the central portion of the sensing wafer WS7.

An opening 101 is formed at the distal end of each passage 81 to open to the front side of the sensing wafer WS7. An opening 102 is formed on the passage 82 to open to the front side of the sensing wafer WS7. In each passage 81, an optical fiber 84 is provided to extend from the opening 101 to the passage 82. In the passage 82, a reflecting mirror 86, collimation lenses 85, and a transmission window 87 are arranged.

A reflecting mirror 104 is arranged at the bottom of each opening 101, and an objective lens 103A is arranged above the reflecting mirror 104. In place of the reflecting mirror 104, a prism may be used. In the opening 102, an objective lens 103B is arranged above the reflecting mirror 86.

Here, as illustrated in FIG. 10A, the objective lenses 103A are provided at a plurality of places he sensing wafer WS7. The optical fibers 84 are arranged in the sensing wafer WS7 to correspond to the respective objective lenses 103A provided at a plurality of places. In this case, the optical fibers 84 may be radially arranged from the central portion of the sensing waferWS7 toward its end portions.

Further, as illustrated in FIG. 10B, a stage ST3 is provided inside the chamber. The sensing wafer WS7 can be placed on the stage ST3. At the central portion of the stage ST3, an opening K3 is formed to penetrate the stage ST3 in the thickness direction. The pening K3 is provided with a transmission window 68 on the front side.

A cylindrical body 73′ is attached below the stage ST3. The distal end of the cylindrical body 73′ may be fixed to the back side of the stage ST3. Inside the cylindrical body 73′, a fiber camera 105 is provided. The fiber camera 105 may include a light source for illuminating an observation object. Outside the cylindrical body 73′, a display 106 is provided.

Next, an explanation will be given of a method of observing an upper electrode 100 inside a chamber by using the sensing wafer WS7.

With reference to FIG. 102, the sensing wafer is transferred into the chamber, and the sensing wafer WS7 is placed on the stage ST3. As illustrated in FIG. 10C, the upper electrode 100 is arranged above the stage ST3.

Then, an illumination light L1 is emitted from the fiber camera 105. The illumination light L1 is transmitted through the transmission windows 68 and 87 and the collimation lenses 85. Further, the illumination light L1 is reflected by the reflecting mirror 86 in radial directions, then comes into the plurality of optical fibers 84, and is guided by the plurality of optical fibers 84. Further, a part of the illumination light L1 goes out upward from the reflecting mirror 86 through the optical fiber 88 of FIG. 7D. Then, the plurality of illumination lights L1 are reflected by the respective reflecting mirrors 104, are then condensed by the objective lenses 103A, and irradiate the upper electrode 100. The part of the illumination light L1 going out upward from the reflecting mirror 86 is condensed by the objective lens 103B, and irradiates the central portion of the upper electrode 100.

When the upper electrode 100 is irradiated with the plurality of illumination lights L1, a plurality of reflection lights L1 are generated from the upper electrode 100. The reflection lights L2 are transmitted through the respective objective lenses 103A, and are reflected by the reflecting mirrors 104. Then, the plurality of reflection lights L2 come into the plurality of optical fibers 84, are guided by the plurality of optical fibers 84, and are then reflected by the respective reflecting surfaces 86A of the reflecting mirror 86. On the other hand, a reflection light L2 reflected from the central portion of the upper electrode 100 is transmitted through the objective lens 103B, and is guided by the optical fiber 88.

Further, all of these reflection lights L2 are transmitted through the collimation lenses 85 and the transmission windows 87 and 68, and go out from the back side of the stage ST3. The plurality of reflection lights L2 going out from the back side of the stage ST3 are incident onto the fiber camera 105, by which an image of the surface of the upper electrode 100 is generated on the basis of the reflection lights L2. The image generated by the fiber camera 105 is displayed by the display 106.

Here, by using the sensing wafer W57, it is possible to observe the surface state of the upper electrode 100, without dismounting the upper electrode 100 from the chamber, even where the distance between the stage ST3 and the upper electrode 100 is small.

As a result of observation on the surface state of the upper electrode 100, for example, if deposits attaching to the surface of the upper electrode 100 are found, the loading of a wafer W into the chamber can be stopped. Then, plasma cleaning is performed to the surface of the upper electrode 100 so that the deposits attaching to the surface of the upper electrode 100 can be removed. At this time, by increasing the gas flow rate at the places where the deposits attach, it is possible to efficiently remove the deposits attaching to the surface of the upper electrode 100.

### Sixth Embodiment

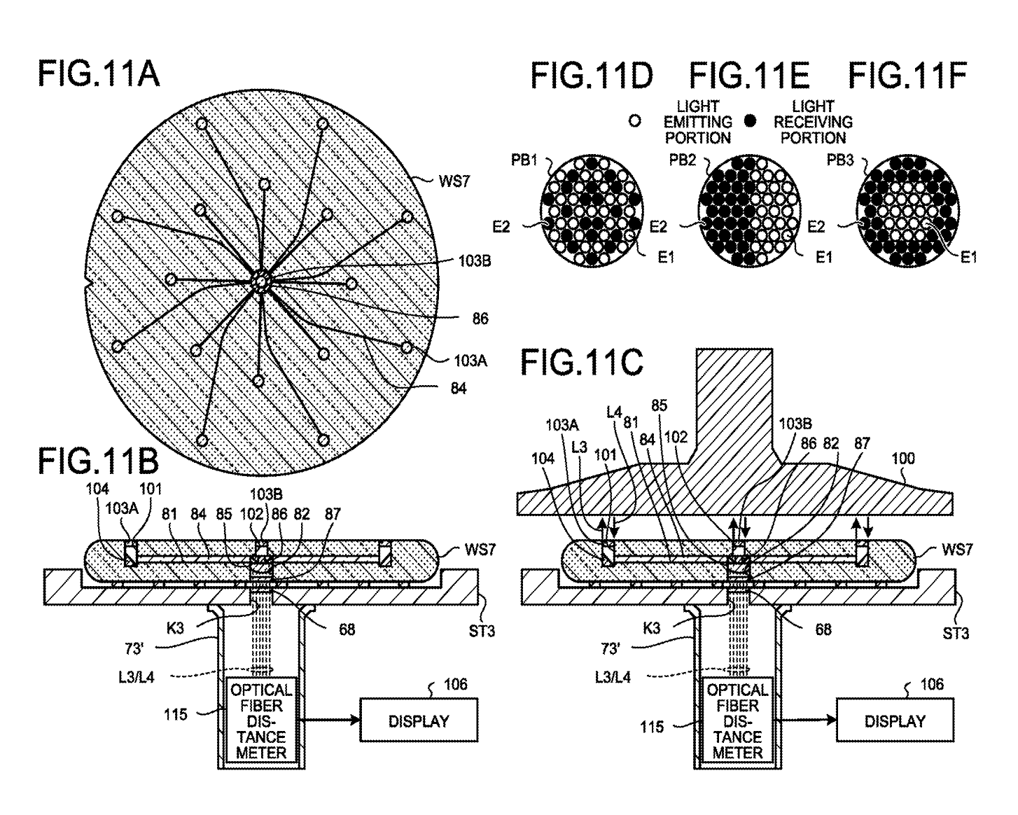

FIG. 11A is a plan view illustrating a schematic configuration of a sensing wafer to be applied to a sensing system according to a sixth embodiment. FIG. 11B is a sectional view illustrating a schematic configuration of the sensing system according to the sixth embodiment. FIG. 11C is a sectional view illustrating an application example of the sensing system according to the sixth embodiment. FIGS. 11D to 11F are plan views illustrating configuration examples of a probe used in an optical fiber distance meter of FIG. 11B. As the optical fiber distance meter, for example, an optical fiber displacement sensor “Fotonic” made by TOYO Corporation (MTI Instruments Inc. of the United States) may be used.

In the system of FIG. 118, in place of the fiber camera 105 of the system of FIG. 10B, an optical fiber distance meter 115 is provided that includes, for example, a light source, a probe, a detector, and a distance calculator. In the system of FIG. 11B, the same sensing wafer WS7 as that in the system of FIG. 10B may be used.

In the optical fiber distance meter 115, for example, halogen light may be used as an incoming light L3. The optical fiber distance meter 115 can acquire the distance to an object on the basis of a change in light amount of a reflection light L4 obtained by irradiating the object with the incoming light L3. The optical fiber distance meter 115 may include a probe for every measurement paint.

In this case, in the optical fiber distance meter 115, a probe PB1 may be used in which light emitting portions E1 and light receiving portions E2 are arranged at random as illustrated in FIG. 110. Alternatively, a probe PB2 may be used in which light emitting portions E1 and light receiving portions E2 are arranged in semicircles as illustrated in FIG. 11E. Alternatively, a probe PB3 may be used in which light emitting portions E1 and light receiving portions E2 are arranged concentrically as illustrated in FIG. 11F.

Here, as illustrated in FIGS. 11A and 11B, in the case of a configuration in which the courses of incoming lights L3 and the courses of reflection lights L4 are changed by the reflecting mirror 86 arranged at the central portion of the sensing wafer WS7, the incoming lights L3 and the reflection lights L4 can be collected to the central portion of the sensing wafer WS7. Accordingly, where the optical fiber distance meter 115 is arranged on the central axis of the sensing wafer WS7, if the optical fiber distance meter 115 is equipped with a single light source and a single detector, the distances at a plurality of measurement points of the sensing wafer WS7 can be obtained all together.

Next, an explanation will be given of a method of measuring the distance to an upper electrode 100 inside a chamber by using the sensing wafer WS7.

With reference to FIG. 115, the sensing wafer WS7 is transferred into the chamber, and the sensing wafer WS7 is placed on the stage ST3, As illustrated in FIG. 11C, the upper electrode 100 is arranged above the stage ST3.

Then, an incoming light L3 is emitted from the optical fiber distance meter 115. The incoming light L3 is transmitted through the transmission windows 68 and 87 and the collimation lenses 85. Further, the incoming light L3 is reflected by the reflecting mirror 86 in radial directions, then comes into the plurality of optical fibers 84, and is guided by the plurality of optical fibers 84. Further, a part of the incoming light L3 goes out upward from the reflecting mirror 86 through the optical fiber 88 of FIG. 7D. Then, the plurality of incoming lights L3 are reflected by the respective reflecting mirrors 104, are then condensed by the objective lenses 103A, and are incident onto the upper electrode 100.

When the plurality of incoming lights L3 are incident onto the upper electrode 100, a plurality of reflection lights L4 are generated from the upper electrode 100. The reflection lights L4 are transmitted through the respective objective lenses 103A, and are reflected by the reflecting mirrors 104. Then, the plurality of reflection lights L4 come into the plurality of optical fibers 84, are guided by the plurality of optical fibers 84, and are then reflected by the respective reflecting surfaces 86A of the reflecting mirror 86. On the other hand, a reflection light L4 reflected from the central portion of the upper electrode 100 is transmitted through the objective lens 103B, and is guided by the optical fiber 88.

Further, all of these reflection lights L4 are transmitted through the collimation lenses 85 and the transmission windows 87 and 68, and go out from the back side of the stage ST3. The plurality of reflection lights L4 going out from the back side of the stage ST3 are incident onto the optical fiber distance meter 115, by which the distances from the sensing wafer WS7 to the upper electrode 100 are calculated on the basis of the light amounts of the reflection lights L4 at respective measurement points. The distances to the upper electrode 100 calculated by the optical fiber distance meter 115 are displayed by the display 106.

Here, by using the sensing wafer WS7, it is possible to place the sensing wafer WS7 on the stage ST3, without moving the upper electrode 100, even where the distance between the stage ST3 and the upper electrode 100 is small. Accordingly, it is possible to estimate, with high accuracy, the distance from a wafer W to the upper electrode 100 set in a plasma process performed inside the chamber.

As a result of calculation on the distances from the sensing wafer WS7 to the upper electrode 100, if the distances from the respective measurement points of the sensing wafer WS7 to the upper electrode 100 are not uniform, the loading of a wafer W into the chamber can be stopped. Then, for example, the inclination of the upper electrode 100 is adjusted so that the distances from the respective measurement points of the sensing wafer WS7 to the upper electrode 100 can become uniform. Accordingly, it is possible to reduce the dimensional unevenness among devices to be formed on a wafer W transferred into the chamber thereafter, and thus to improve the quality of the devices to be formed on the wafer W.

### Seventh Embodiment

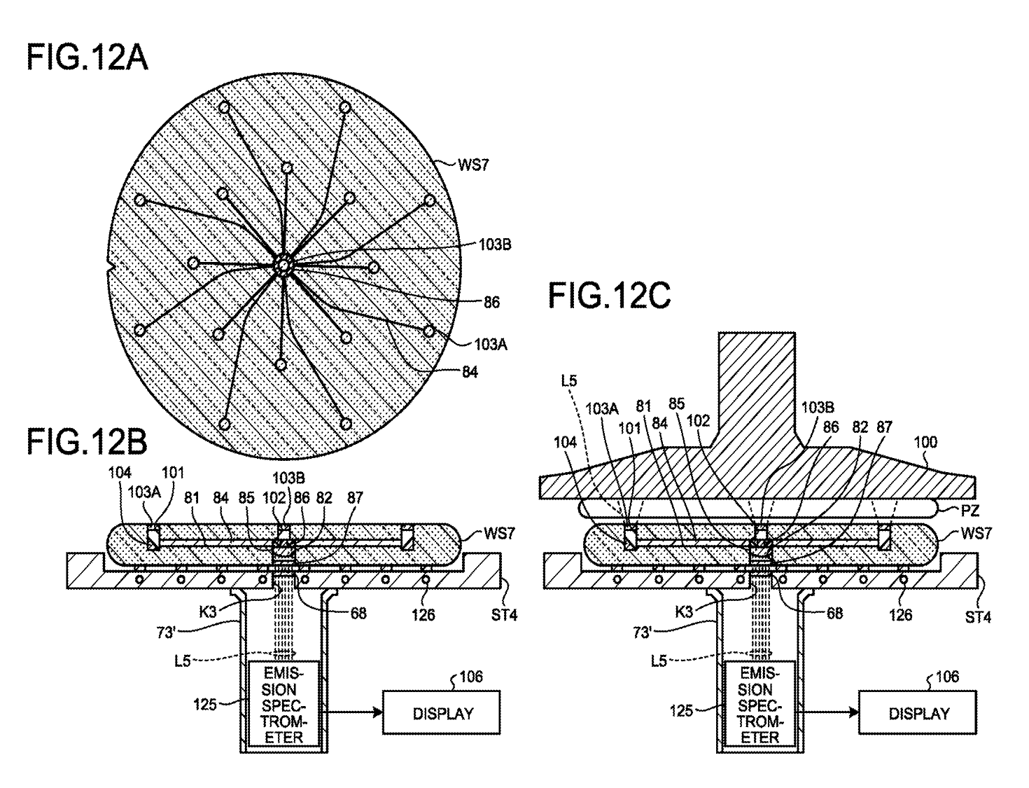

FIG. 12A is a plan view illustrating a schematic configuration of a sensing wafer to be applied to a sensing system according to a seventh embodiment. FIG. 12B is a sectional view illustrating a schematic configuration of the sensing system according to the seventh embodiment. FIG. 12C is a sectional view illustrating an application example of the sensing system according to the seventh embodiment.

In the system of FIG. 12B, in place of the fiber camera 105 of the system of FIG. 10B, an emission spectrometer 125 is provided. The emission spectrometer 125 can qualitatively detect the excitation state of plasma PZ from the wavelength of a bright line spectrum inherent to an element, and quantify a chemical species present in the plasma PZ from the light emitting intensity of a predetermined wavelength.

In the system of FIG. 12B, the same sensing wafer WS7 as that in the system of FIG. 10B may be used. In the system of FIG. 12B, a stage ST4 may be used in place of the stage of FIG. 10B. The stage ST4 may be configured as in the stage ST3, except that heaters 126 are added to the stage ST3. The heaters 126 may be composed of about several hundred heaters, and may be concentrically arranged in the stage ST4. The heaters 126 can be individually controlled in temperature.

Next, an explanation will be given of a methodof measuring the planar light emitting distribution of plasma PZ inside the chamber by using the sensing wafer WS7.

With reference to FIG. 125, the sensing wafer WS7 is transferred into the chamber, and the sensing wafer WS7 is placed on the stage ST4. As illustrated in FIG. 12C, an upper electrode 100 is arranged above the stage ST4.

Then, plasma lights L5 are emitted by the plasma PZ during a plasma etching process. The plasma lights L5 are transmitted through the respective objective lenses 103A, and are reflected by the reflecting mirrors 104. The plasma lights L5 are light including a bright line spectrum inherent to an element, whichis emitted in accordance with the excitation state of the plasma PZ. Then, the plurality of plasma lights 15 come into the plurality of optical fibers 84, are guided by the plurality of optical fibers 84, and are then reflected by the respective reflecting surfaces 86A of the reflecting mirror 86. On the other hand, a plasma light L5 emitted from the central portion of the plasma PZ is transmitted through the objective lens 103B, and is guided by the optical fiber 88 of FIG. 7D,

Further, all of these plasma lights L5 are transmitted through the collimation lenses 85 and the transmission windows 87 and 68, and go out from the back side of the stage ST4. The plurality of plasma lights L5 going out from the back side of the stage ST4 are incident onto the emission spectrometer 125, by which the planar intensity distribution of the plasma lights L5 is detected. The planar intensity distribution detected by the emission spectrometer 125 is displayed by the display 106.

Here, by using the sensing wafer WS7, it is possible to detect the planar intensity distribution of the plasma lights L5 during a plasma etching process. Accordingly, it is possible to calculate the planar intensity distribution of the plasma lights L5 with accuracy equivalent to that obtained when the plasma process is performed to a wafer W for forming devices inside the chamber.

As a result of calculation on the planar intensity distribution of the plasma lights L5, if the planar intensity distribution of the plasma lights L5 is not uniform, the process to a wafer W under this condition inside the chamber can be stopped. Then, for example, the temperature of the heaters 126 is controlled to change the temperature distribution of the stage ST4 in accordance with the planar intensity distribution of the plasma lights L5. Thus, the non-uniformity in the planar intensity distribution of the plasma lights L5 can be corrected, whereby the processing dimensions can be made uniform. Accordingly, it is possible to perform the process to the wafer W under optimized process conditions, to reduce the dimensional unevenness among devices to be formed on the wafer W, and thus to improve the quality of the devices to be formed on the wafer W.

Here, in order to uniformize the planar intensity distribution of the plasma lights L5, the flow rate distribution of the G1 may be varied in accordance with the planar intensity distribution of the plasma lights L5.

### Eighth Embodiment

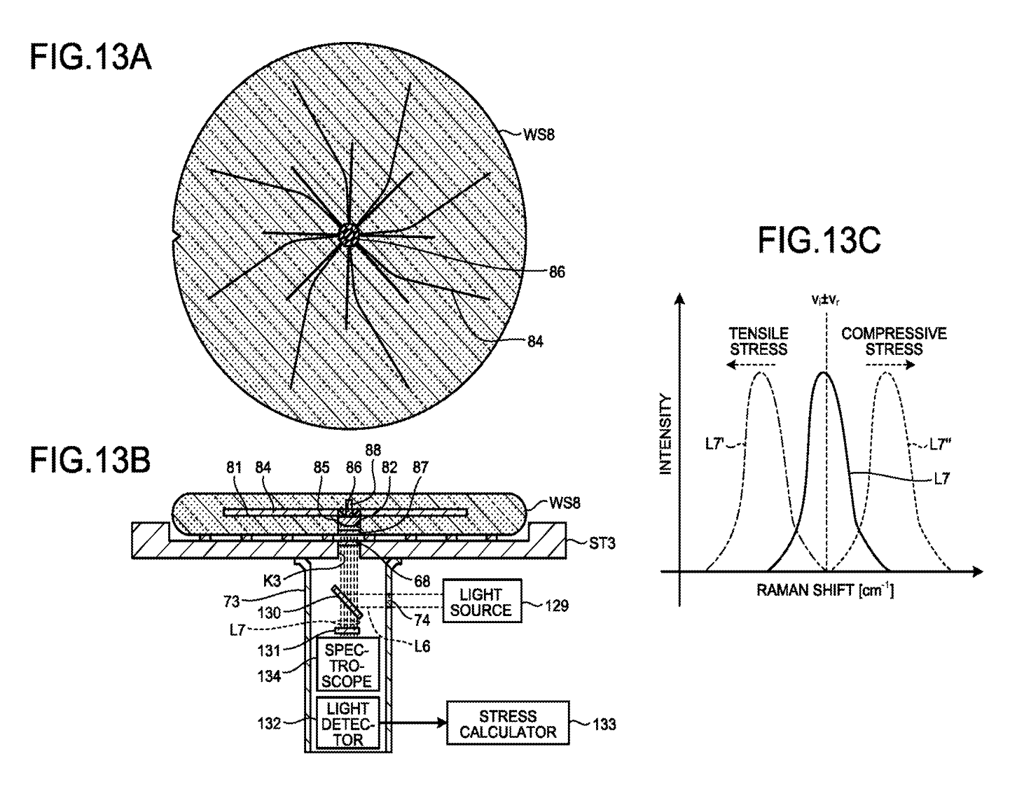

FIG. 13A is a plan view illustrating a schematic configuration of a sensing wafer to be applied to a sensing system according to an eighth embodiment. FIG. 13B is a sectional view illustrating a schematic configuration of the sensing system according to the eighth embodiment.

As illustrated in FIG. 132, passages 81 are formed below the front side of the sensing wafer WS8. A passage 82 is formed at the central portion of the sensing wafer WS8. In each passage 81, an optical fiber 84 is provided to extend from the distal end of this passage 81 to the passage 82. The distal end of each passage 81 may be terminated inside the wafer substrate of the sensing wafer WS8. In the passage 82, a reflecting mirror 86, collimation lenses 85, and a transmission window 87 are arranged.

Here, as illustrated in FIG. 13A, the distal ends of the passages 81 may be terminated at a plurality of places of the wafer substrate of the sensing wafer WS8. The optical fibers 84 are arranged in the sensing wafer to correspond to the respective passages 81 formed at a plurality of places. In this case, the optical fibers 84 may be radially arranged from the central portion of the sensing wafer WS8 toward its end portions. The distal ends of the optical fibers 84 are preferably arranged at almost regular intervals in the sensing wafer WS8.

Further, as illustrated in FIG. 138, a cylindrical body 73 is attached below the stage ST3. The cylindrical body 73 is provided with a transmission window 74 on the lateral side. Inside the cylindrical body 73, a half mirror 130, a filter 131, a spectroscope 134, and a light detector 132 are provided. Outside the cylindrical body 73, a light source 129 and a stress calculator 133 are provided. The single light source 129 and the single light detector 132 can be used for a plurality of Raman scattering lights L7 in common.

The light source 129 generates an incoming light L6 to come into the optical fibers 84. As the incoming light L6, laser light may be used. The half mirror 130 reflects the incoming light L6, and transmits the Raman scattering lights L7. The filter 131 transmits a frequency component of the Raman scattering lights L7, and attenuates the other frequency components. The spectroscope 134 spectrally disperses the Raman scattering lights L7. The light detector 132 detects the Raman scattering lights L7. Here, the light detector 132 can simultaneously detect the plurality of Raman scattering lights L7. The stress calculator 133 calculates the stress of the sensing wafer WS8 on the basis of the Raman shift amounts of the Raman scattering lights L7.

Next, an explanation will be given of a method of measuring a stress during a plasma process inside the chamber by using the sensing wafer WS8.

With reference to FIG. 135, the sensing wafer WS8 is transferred into the chamber, and the sensing wafer WS8 is placed on the stage ST3.

Then, during the plasma etching process, an incoming light L6 is emitted from the light source 129 Then, the incoming light L6 is transmitted through the transmission window 74, is reflected by the half mirror 130, and is then transmitted through the transmission windows 68 and 87 and the collimation lenses 85. Further, the incoming light L6 is reflected by the reflecting mirror 86 in radial directions, and then comes into the plurality of optical fibers 84. The incoming light L6 is guided by the plurality of optical fibers 84, and is incident onto the wafer substrate of the sensing wafer WS8. Further, a part of the incoming light L6 is incident onto the central portion of the wafer substrate of the sensing wafer WS8 through the optical fiber 88.

Raman scattering lights L7 are emitted from the wafer substrate of the sensing wafer WS8, in response to the incidence of the incoming light L6, and come into the optical fibers 84. The respective Raman scattering lights L7 are guided by the optical fibers 84, and are reflected by the respective reflecting surfaces 86A of the reflecting mirror 86. On the other hand, a Raman scattering light L7 emitted from the central portion of the wafer substrate of the sensing wafer WS8 is guided by the optical fiber 88.

Further, all of these Raman scattering lights L7 are condensed by the collimation lenses 85, are then transmitted through the transmission windows 87 and 68, and go out from the back side of the stage ST3. The plurality of Raman scattering lights L7 going out from the back side of the stage ST3 are transmitted through the half mirror 130, and a desired wavelength band component is extracted therefrom by the filter 131, and is spectrally dispersed for every specific wavelength component by the spectroscope 134.

The Raman scattering lights L7 spectrally dispersed for every specific wavelength component are incident onto the light detector 72, by which the specific wavelength components of the Raman scattering lights L7 are detected. The detection result obtained by the light detector 132 is sent to the stress calculator 133. Upon reception of the detection result from the light detector 132, the stress calculator 133 calculates the stress distribution of the sensing wafer WS8 on the basis of the Raman shifts of the specific wavelength component the Raman scattering lights L7.

FIG. 13C is a diagram illustrating the relationship between the stress measured by the sensing system according to the eighth embodiment and the Raman shift.

As illustrated in FIG. 130, when an incoming light L6 having a vibration frequency νᵢ is incident onto the substrate crystal of the sensing wafer WS8, a Raman scattering light L7 having a vibration frequency νᵢ±νᵣ is emitted by an interaction with lattice vibration of the substrate crystal, where νᵣ denotes the vibration frequency of the lattice vibration. The vibration frequency νᵣ of the lattice vibration depends on the bonding force of the substrate crystal.

As the lattice interval the substrate crystal becomes larger because of a tensile stress acting on the substrate crystal, the bonding force of the substrate crystal decreases, and the vibration frequency of the lattice vibration becomes lower. Accordingly, a Raman scattering light L7′ is emitted to have a peak shifted on the lower frequency side as compared with the Raman scattering light L7.

On the other hand, as the lattice interval the substrate crystal becomes smaller because of a compressive stress acting on the substrate crystal, the bonding force of the substrate crystal increases, and the vibration frequency of the lattice vibration becomes higher. Accordingly, a Raman scattering light. L7″ is emitted to have a peak shifted on the higher frequency side as compared with the Raman scattering light L7.

Here, by using the sensing wafer WS8, it is possible to detect the stress distribution of the sensing wafer WS8 during the plasma etching process. Accordingly, it is possible to calculate the stress distribution with accuracy equivalent to that obtained when the plasma process is performed to a wafer W for forming devices inside the chamber.

As a result of calculation on the stress distribution of the sensing wafer WS8, if the stress distribution of the sensing wafer W38 is not uniform, the process to a wafer W under this condition inside the chamber can be stopped. Then, for example, the flow rate distribution of the gas G1 is varied in accordance with the stress distribution of the sensing wafer WS8, whereby the stress distribution of the sensing wafer WS8 can be made uniform. Accordingly, it is possible to perform the process to the wafer W under optimized process conditions, to reduce the dimensional unevenness among devices to be formed on the wafer W, and thus to improve the quality of the devices to be formed on the wafer W.

### Ninth Embodiment

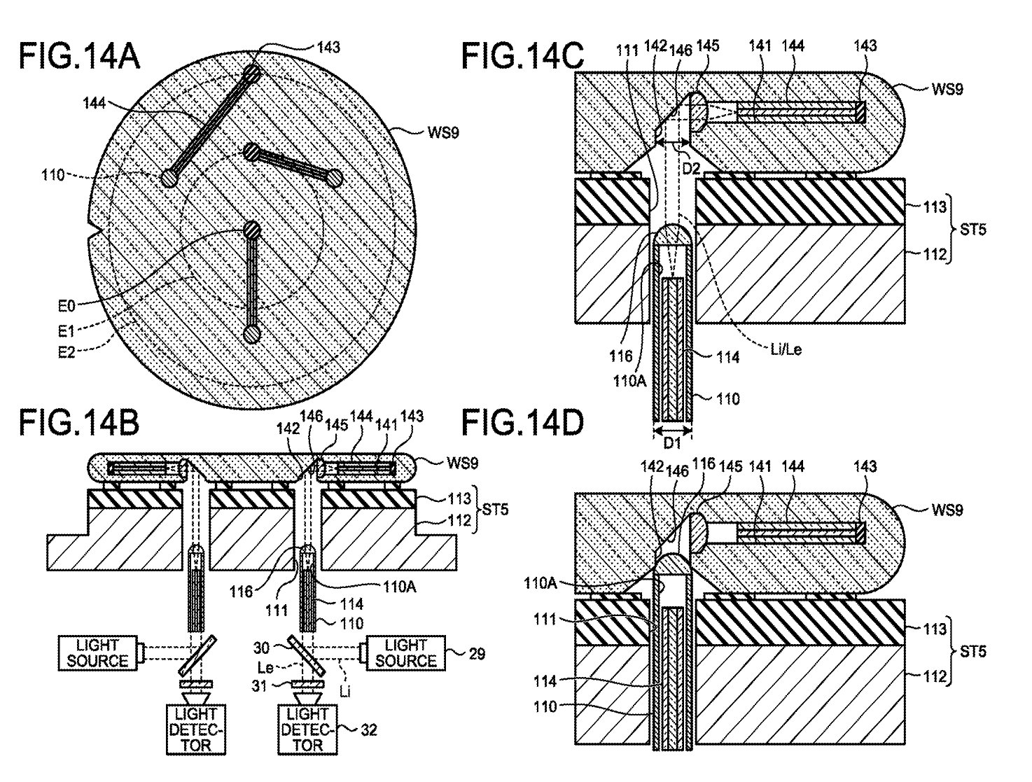

FIG. 14A is a plan view illustrating a schematic configuration of a sensing wafer o be applied to a plasma processing apparatus according to a ninth embodiment. FIG. 14B is a sectional view, illustrating a schematic configuration of a temperature measuring system in a case where the sensing wafer of FIG. 14A is applied to the plasma processing apparatus. FIG. 14C is a sectional view illustrating an optical waveguide part of FIG. 14B in an enlarged state. FIG. 14D is a sectional view illustrating a contact state of a wafer with a pin in moving the wafer up/down.

As illustrated in FIG. 14B, a stage ST5 is disposed inside the chamber of the plasma processing apparatus. The stage ST5 includes a pedestal 112 and an electrostatic chuck 113.

A sensing wafer WS9 can be placed on the stage ST5. The stage ST5 includes through holes 111 formed therein. The through holes 111 may penetrate the pedestal 112 and the electrostatic chuck 113 in the vertical direction. Each through hole 111 is provided with a pin 110 inside. The pin 110 can be moved up and down. In this case, the sensing wafer WS9 can be moved up and down by moving the pins 110 up and down, when the sensing wafer W59 is to be transferred.

An optical fiber 114 is inserted in each pin 110. Each pin 110 may include a hollow 110A in which the optical fiber 114 is inserted. The hollow 110A may be formed to extend from the proircial end of the pin 110 to its distal end. The optical fiber 114 can cause an incoming light Li emitted from below the stage ST5 to come in from the back side of the sensing wafer WS9, and cause an outgoing light Le emitted from the back side of the sensing wafer WS9 to go out downward from the stage ST5. A collimation lens 116 is provided at the distal end of each pin 110. Below the stage ST5, sets of a light source 29, a half mirror 30, a light-filter 31, and a light detector 32 are provided.

On the other hand, excitation light emitters 43 are embedded in the sensing wafer WS9. As illustrated in FIG. 14A, the excitation light emitters 143 may be arranged one by one at the midmost part E0 of the sensing wafer WS9 and on concentric circles E1 and E2 having different radii. Because plasma changes in density concentrically above the sensing wafer WS9, the temperature distribution also changes concentrically above the sensing wafer WS9. Accordingly, where the excitation light emitters 143 are arranged one by one at the midmost part E0 of the sensing wafer WS9 and on concentric circles E1 and E2 having different radial, it is possible to improve the temperature distribution measurement accuracy on the sensing wafer WS9, while reducing the arrangement number of excitation light emitters 143.

Passages 142 are formed in the sensing wafer WS9 to correspond to the arrangement positions of the respective pins 110. The passages 142 may be formed in the vertical direction from the back side of the sensing wafer WS9. The passages 142 may be formed not to penetrate the front side of the sensing wafer WS9. A reflecting mirror 146 is arranged at the distal end of each passage 142. The reflecting mirror 146 may be provided by mirror-finishing the distal end of each passage 142, or may be provided by setting a reflecting surface at the distal end of each passage 142. The reflecting mirror 146 may be made of the same material as the wafer substrate of the sensing wafer WS9, or may be made of a different material from the wafer substrate of the sensing wafer WS9.

Passages 141 are formed below the front side of the sensing wafer WS9. The passages 141 may be formed to extend from the respective excitation light emitters 143 toward the passages 142. In each passage 141, an optical fiber 144 is provided to extend from the corresponding excitation light emitter 143 to the corresponding passage 142. The distal end of each passage 142 may be coupled with the proximal end of the corresponding passage 111. A collimation lens 145 is arranged at the proximal end of each passage 141. The collimation lens 145 may be arranged in the light reflecting direction of the corresponding reflecting mirror 146.

Here, as illustrated in FIG. 14C, the diameter D2 of each passage 142 may be set small than the diameter D1 of each pin 110. Consequently, as illustrated in FIG. 14D, when the sensing wafer WS9 is to be transferred, even though the pins 110 are moved up to raise the sensing wafer WS9, the distal end portion of each collimation lens 116 can be prevented from coming into contact with the sensing wafer WS9. Accordingly, when the sensing wafer WS9 is to be transferred, it is possible to prevent the distal end portion of the collimation lens 116 from being damaged and/or contaminated, and thus to prevent deterioration of the light-condensing characteristic of the collimation lens 116.

Next, an explanation will be given of a method of measuring a temperature during a plasma process inside the chamber by using the sensing wafer WS9.

With reference to FIG. 140, when the sending wafer WS9 is to be transferred into the chamber 1, the pins 110 are projected upward from the electrostatic chuck 113. Then, the sensing wafer WS9 is transferred onto the pins 110 to place the sensing wafer WS9 on the pins 110. The pins 110 are moved down in a state where the sensing wafer WS9 is placed on the pins 110, and the sensing wafer WS9 is thereby placed onto the electrostatic chuck 113. Then, the sensing wafer 1S9 is attracted by the electrostatic chuck 113, and thus the sensing wafer WS9 is fixed on the electrostatic chuck 113.

When the temperature of the sensing wafer WS9 is to be measured during a plasma etching process, the distal ends of the pins 110 may be separated from the sensing wafer WS9. At this time, as illustrated in FIG. 140, the distal end of each pin 110 may be set to stay inside the corresponding through hole 111 of the stage ST5.

Then, an incoming light Li is emitted from each light source 29. The incoming light Li is reflected by the corresponding half mirror 30, and then comes into the corresponding optical fiber 114. The incoming light Li is guided by this optical fiber 114 in the vertical direction, is then condensed by the corresponding collimation lens 116, and is reflected by the corresponding reflecting mirror 146 to change the traveling direction of the incoming light Li into the horizontal direction. Then, the incoming light Li is condensed by the corresponding collimation lens 145, and comes into the corresponding optical fiber 144. Then, the incoming light Li is guided by this optical fiber 144 in the horizontal direction, and is incident onto the corresponding excitation light emitter 143.

At each excitation light emitter 143, an outgoing light Le is generated in response to the incidence of the corresponding incoming light Li, and comes into the corresponding optical fiber 144. The outgoing light Le is guided by this optical fiber 144 in the horizontal direction, passes through the corresponding collimation lens 145, and is then reflected by the corresponding reflecting mirror 146 to change the traveling direction of the outgoing light Le into the vertical direction. Further, the outgoing light Le passes through the corresponding collimation lens 116, then comes into the corresponding optical fiber 114, and is guided by this optical fiber 114 in the vertical direction. Further, the outgoing light Le is transmitted through the corresponding half mirror 30, and a desired wavelength component is extracted therefrom by the light-filter 31, and is incident onto the corresponding light detector 32, by which the outgoing light Le is detected. Upon detection of the outgoing light Le, the temperature of the sensing wafer WS9 is calculated on the basis of a temperature characteristic of the outgoing light Le.

Here, as the optical fiber 114 is provided in each pin 110 to cause the incoming light Li to come in from the back side of the sensing wafer WS9, and to cause the outgoing light Le to go out from the back side of the sensing wafer WS9, each through hole 111 for moving the pin 110 up and down can be used as a passage for the incoming light Li and outgoing light Le. Accordingly, in order to provide the passage for the incoming light Li and outgoing light Le, there is no need to perform a drilling process to the stage ST5, other than processes for the through holes 111. This makes it possible to reduce the man hour necessary for performing drilling processes to the stage ST5.

Here, the stage ST5 and the pins 110 may be used in place of the stage ST3 and the sensing wafer WS7 illustrated in FIGS. 10B and 10C. In this case, in place of each set of the light source 29, half mirror 30, light-filter 31, and light detector 32 illustrated in FIG. 14P, the fiber camera 105 of FIGS. 105 and 10C may be used. Then, when the surface state of the upper electrode 100 is to be observed as in FIG. 10C, the pins 110 can be projected upward from the stage STS in a state where the sensing wafer WS9 is not present on the stage ST5, and irradiate the upper electrode 100 with an illumination light L1. Consequently, it is possible to observe the surface state of the upper electrode 100, without using the sensing wafer WS7.

### Tenth Embodiment

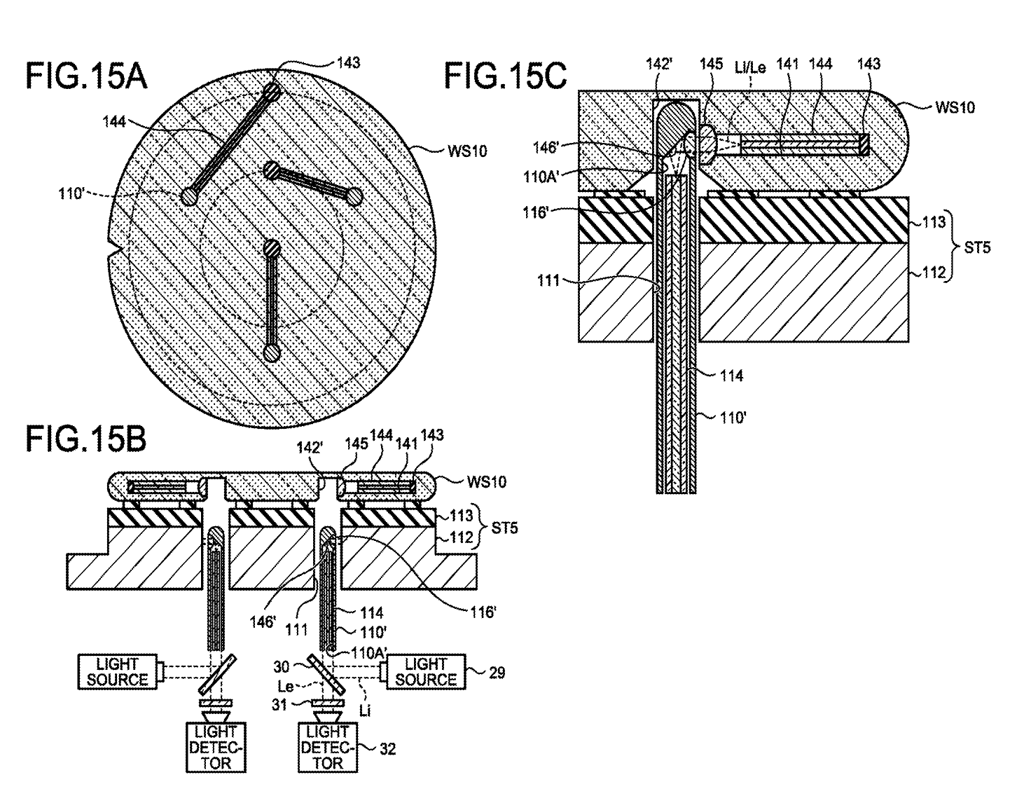

FIG. 15A is a plan view illustrating a schematic configuration of a sensing wafer to be applied to a plasma processing apparatus according to a tenth embodiment. FIG. 15B is a sectional view illustrating a schematic configuration of a temperature measuring system in a case where the sensing wafer of FIG. 15A is applied to the plasma processing apparatus. FIG. 15C is a sectional view illustrating an optical waveguide part of FIG. 15B in an enlarged state.

In the plasma processing apparatus of FIG. 15B, in place of the pins 110 of the plasma processing apparatus of FIG. 14B, pins 110′ are provided. In the plasma processing apparatus of FIG. 15B, in place of the sensing wafer WS9 of FIGS. 14A and 143, a sensing wafer WS10 of FIGS. 15A and 15B may be used.

An optical fiber 114 is inserted in each pin 110′. Each pin 110′ may include a hollow 110A′ in which the optical fiber 114 is inserted. The hollow 110A′ may be formed not to penetrate the distal end of the pin 110′. In each pin 110′, a reflecting mirror 146′ is arranged at the distal end of the hollow 110A′. A collimation lens 116′ is provided on the lateral side of each pin 110′. The collimation lens 116′ may be arranged between the reflecting mirror 146′ and the distal end of the optical fiber 114.

The sensing wafer WS10 includes passages 142′ formed therein in place of the passages 142 and reflecting mirrors 146 of the sensing wafer WS9. The passages 142′ may be formed in the vertical direction from the back side of the sensing wafer WS10. The passages 142′ may be formed not to penetrate the front side of the sensing wafer WS10. Each pin 110′ can be inserted into the corresponding passage 142′ from the back side of the sensing wafer WS10.

Next, an explanation will be given of a method of measuring a temperature during a plasma process inside the chamber by using the sensing wafer WS10.

With reference to FIG. 15H, the sensing wafer WS10 is transferred into the chamber 1, while the pins 110′ are projected upward from the electrostatic chuck 113. Then, the sensing wafer WS10 is transferred onto the pins 110′ to place the sensing wafer WS10 on the pins 110′. At this time, the pins 110′ can be inserted into the respective passages 142′. Here, as the collimation lens 116′ is provided on the lateral side of each pin 110′, it is possible to prevent the collimation lens 116′ from being damaged and/or contaminated, even though the distal end of each pin 110′ comes into contact with the sensing wafer WS10 through the corresponding passage 142′, when the sensing wafer WS10 is to be transferred.

After the sensing wafer WS10 is placed on the pins 110′, the pins 110′ are moved down, and the sensing wafer WS10 is thereby placed onto the electrostatic chuck 113. Then, the sensing wafer WS10 is attracted by the electrostatic chuck 113, and thus the sensing wafer WS10 is fixed on the electrostatic chuck 113.

When the temperature of the sensing wafer WS10 is to be measured during a plasma etching process, the distal ends of the pins 110′ may be separated from the sensing wafer WS10. At this time, as illustrated in FIG. 15C, the distal end of each pin 110′ may be set to stay inside the corresponding passage 142′ of the sensing wafer WS10. Further, the collimation lenses 116′ and 145 may be set to face each other.

Then, an incoming light Li is emitted from each light source 29. The incoming light Li is reflected by the corresponding half mirror 30, and then comes into the corresponding optical fiber 114. The incoming light Li is guided by this optical fiber 114 in the vertical direction, and is then reflected by the corresponding reflecting mirror 146′ to change the traveling direction cf the incoming light Li into the horizontal direction. Thus, the incoming light passes through the corresponding collimation len 116′. Then, the incoming light Li is condensed by the corresponding collimation lens 145, and comes into the corresponding optical fiber 144. Then, the incoming light Li is guided by this optical fiber 144 in the horizontal direction, and is incident onto the corresponding excitation light emitter 143.

At each excitation light emitter 143, an outgoing light Le is generated in response to the incidence of the corresponding incoming light Li, and comes into the corresponding optical fiber 144. The outgoing light Le is guided by this optical fiber 144 in the horizontal direction, passes through the corresponding collimation lens 145, and is then condensed by the corresponding collimation lens 116′. Then, the outgoing light Le is reflected by the corresponding reflecting mirror 146′ to change the traveling direction of the outgoing light Le into the vertical direction. Further, the outgoing light Le comes into the corresponding optical fiber 114, is guided by this optical fiber 114 in the vertical direction, and is then transmitted through the corresponding half mirror 30. Then, a desired wavelength component is extracted from the outgoing light Le by the light-filter 31, and is incident onto the corresponding light detector 32, by which the outgoing light Le is detected. Upon detection of the outgoing light Le, the temperature of the sensing, wafer WS10 is calculated on the basis of a temperature characteristic of the outgoing light Le.

Here, as the optical fiber 114 is provided in each pin 110′ to cause the incoming light Li to come in from the back side of the sensing wafer WS10, and to cause the outgoing light Le to go out from the back side of the sensing wafer WS10, each through hole 111 for moving the pin 110′ up and down can be used as a passage for the incoming light Li and outgoing light Le. Accordingly, in order to provide the passage for the incoming light Li and outgoing light Le, there is no need to perform a drilling process to the stage ST5, other than processes for the through holes 111. This makes it possible to reduce the man hour necessary for performing drilling processes to the stage ST5.

### Eleventh Embodiment

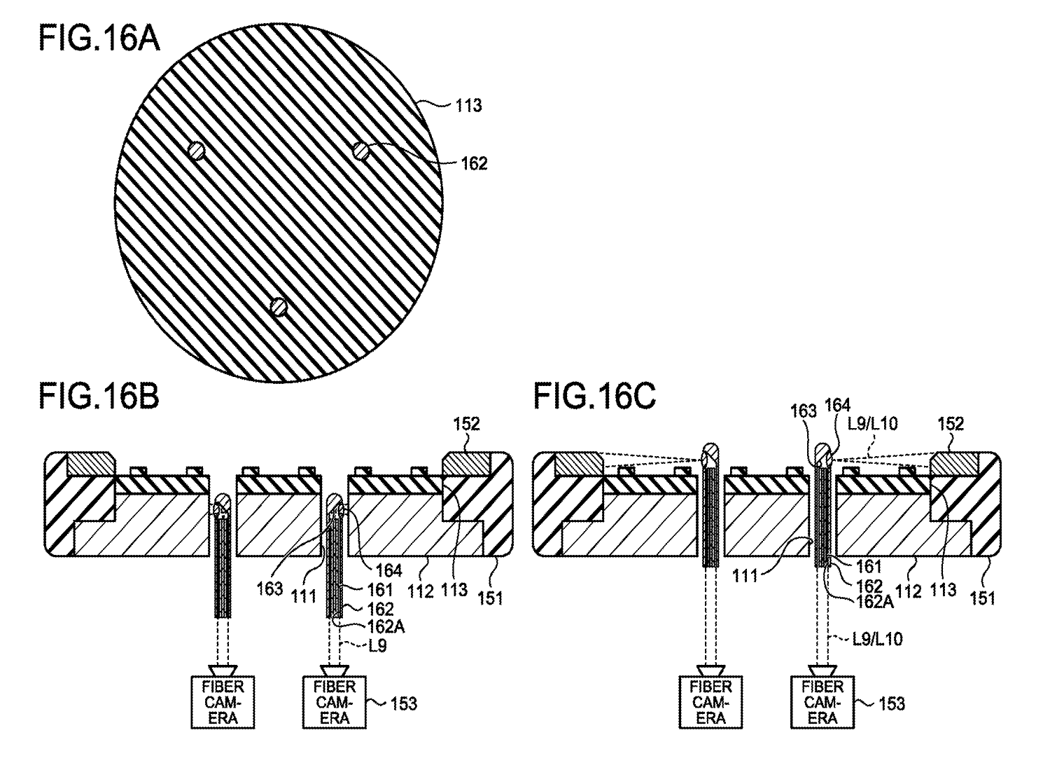

FIG. 16A is a plan view illustrating an arrangement example of pins on an electrostatic chuck applied to a plasma processing apparatus according to an eleventh embodiment. FIG. 16B is a sectional view illustrating the positions of the pins before observation of a focus ring performed by a sensing system applied to the plasma processing apparatus according to the eleventh embodiment. FIG. 16C is a sectional view illustrating the positions of the pins in observation of the focus ring performed by the sensing system applied to the plasma processing apparatus according to the eleventh embodiment.

In the plasma processing apparatus of FIG. 16B, in place of the pins 110′ of the plasma processing apparatus of FIGS. 15A and 15B, pins 162 of FIGS. 16A and 16B are provided. The pins 162 may be arranged as in the pins 110′. Further, in the plasma processing apparatus of FIG. 16B, in place of each set of the light source 29, half mirror 30, light-filter 31, and light detector 32 illustrated in FIG. 15B, a fiber camera 153 including a built-in light source of an irradiation light L9 is provided.

Further, in the plasma processing apparatus of FIG. 16B, a focus ring 152 is arranged to surround the periphery of the wafer mounting region on the electrostatic chuck 113. An insulating ring 151 that supports the focus ring 152 is provided at the periphery of the stage ST5.

An optical fiber 161 is inserted in each pin Each pin 162 may include a hollow 162A in which the optical fiber 161 is inserted. The hollow 162A may be formed not to penetrate the distal end of the pin 162. In each pin 162, a reflecting mirror 163 is arranged at the distalend of the hollow 162A. A light-condensing lens 164 is provided on the lateral side of each pin 162. The light-condensing lens 164 may be arranged between the reflecting mirror 163 and the distal end of the optical fiber 161.

Next, an explanation will be given of a method of observing the wear-out state of the focus ring 152 by using the bins 162.

With reference to FIG. 16B, when a wafer is not present inside the chamber, the pins 162 may be set to stay inside the through holes 111 in a lowered state. Then, when the wear-out state of the focus ring 152 is to be observed, as illustrated in FIG. 16C, the pins 162 are moved up and projected upward from the electrostatic chuck 113. At this time, an illumination light L9 is emitted from each fiber camera 153. The illumination light L9 comes into the corresponding optical fiber 161, is guided by this optical fiber 161 in the vertical direction, and is then reflected by the corresponding reflecting mirror 163 to change the traveling direction of the illumination light L9 into the horizontal direction. Then, the illumination light L9 is condensed by the corresponding light-condensing lens 164, and irradiates the inner peripheral surface of the focus ring 152.

When the inner peripheral surface of the focus ring 152 is irradiated with the illumination light L9, a reflection light L10 is generated from the inner peripheral surface of the focus ring 152. The reflection light L10 passes through the light-condensing lens 164, and is reflected by the reflecting mirror 163 to change the traveling direction of the reflection light L10 into the vertical direction. Then, the reflection light L10 comes into the corresponding optical fiber 161, and is guided by this optical fiber 161 in the vertical direction. Then, the reflection light L10 is incident onto the corresponding fiber camera 153, by which an image of the inner peripheral surface of the focus ring 152 is generated on the basis of the reflection light L10.

The image of the inner peripheral surface of the focus ring 152 can be used to determine the wear-out state of the focus ring 152 When it is determined that the wear-out of the focus ring 152 is serious, the focus ring 152 can be replaced.

Here, as the pins 162 are used to observe the inner peripheral surface of the focus ring 152, it is possible to determine the wear-out state of the focus ring 152 without opening the chamber of the plasma processing apparatus to the atmosphere.

Further, as the optical fiber 161 is provided in each pin 162 to irradiate the inner peripheral surface of the focus ring 152 with the illumination light L9, each through hole 111 for moving the pin 162 up and down can be used as a passage for the illumination light L9 and reflection light L10. Accordingly, in order to provide the passage for the illumination light L9 and reflection light. L10, there is no need to perform a drilling process to the stage ST5, other than processes for the through holes 111. This makes it possible to reduce the man hour necessary for performing drilling processes to the stage ST5.

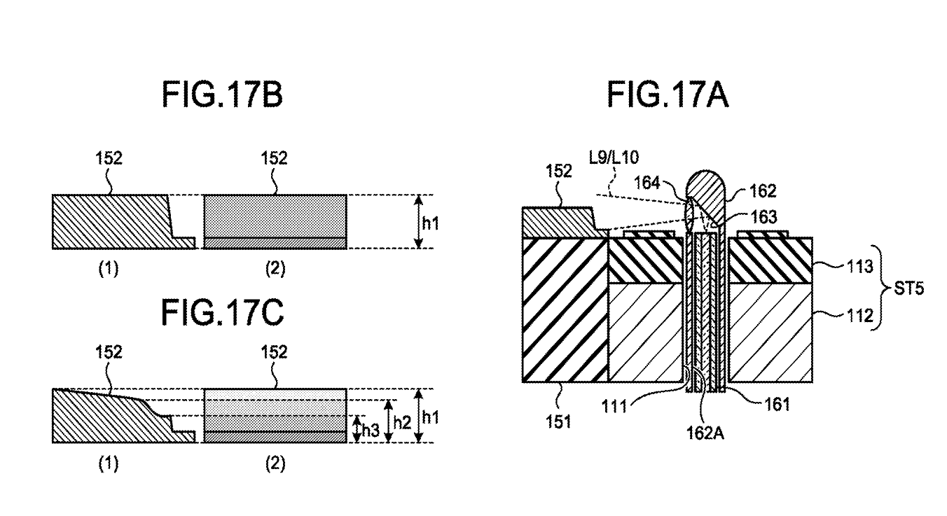

FIG. 17A is a sectional view illustrating a state of observation of the focus ring performed by the sensing system applied to the plasma processing apparatus according to the eleventh embodiment. In FIG. 17B, (1) illustrates a sectional view of a state of the focus ring of FIG. 17A before its wear-out. In FIG. 17B, (2) illustrates a diagram of a state of the inner peripheral surface of the focus ring of FIG. 17A before its wear-out. In FIG. 172, (1) illustrates a sectional view of a state of the focus ring of FIG. 17A after its wear-out. In FIG. 172, (2) illustrates a diagram of a state of the inner peripheral surface of the focus ring of FIG. 17A after its wear-out.

As illustrated in (1) of FIG. 175, before the focus ring is worn out, the inner peripheral surface of the focus ring 152 is in an almost vertically standing state. On the other hand, as illustrated in (1) of FIG. 17C, when the focus ring 152 is worn out, the inclination of the inner peripheral surface of the focus ring 152 becomes larger from the upper side.

Here, as the inclination of the inner peripheral surface of the focus ring 152 is larger, the light intensity of the reflection light L10 becomes lower. Accordingly, as illustrated in (2) of FIGS. 17B and (2) of FIG. 17C, depending on the inclination of the inner peripheral surface of the focus ring 152, the brightness of the inner peripheral surface of the focus ring 152 under observation varies.

As a result, by detecting the brightness of the inner peripheral surface of the focus ring 152 under observation, it is possible to determine the wear-out degree of the focus ring 152 with respect to its height. For example, it is assumed that the height of the focus ring 152 is h1. In this case, as illustrated in (2) of FIG. 17B, when the brightness under observation at the part up to the height h1 of the focus ring 152 is a predetermined value or more, it can be determined that the focus ring 152 has not yet been worn out.

On the other hand, as illustrated in (2) FIG. 17C, when the brightness under observation at the part up to a height h3 of the focus ring 152 is the same as the brightness before wear-out, it can be determined that the focus ring 152 has not yet been worn out at the part up to the height h3. Further, it is assumed that the brightness under observation at the part with heights from h2 to h1 of the focus ring 152 is lower than the brightness before wear-out, and the brightness under observation at the part with heights from h1 to h2 of the focus ring 152 is further lower than the brightness at the part with heights from h2 to h1. In this case, it can be determined that the focus ring 152 has been worn out at the part with heights from h2 to h3 as well as at the part with heights from h1 to h2. Further, the wear-out degrees at these parts can be determined on the basis of the variation amounts in light intensity at these parts.

Here, in order to improve the measurement accuracy of the wear-out state of the focus ring 152, it may be adopted to alternately repeat a step of moving the pins 162 by a certain distance in the vertical direction, in a state where the pins 162 are projected upward from the electrostatic chuck 113, and a step of observing the inner peripheral surface of the focus ring 152. For example, the pins 162 are projected to align the central position of each light-condensing lens 164 with the height hl, and then the inner peripheral surface of the focus ring 152 is observed. Then, the pins 162 are projected to align the central position of each light-condensing lens 164 with the height h2, and then the inner peripheral surface of the focus ring 152 is observed. Then, the pins 162 are projected to align the central position of each light-condensing lens 164 with the height h3, and then the inner peripheral surface of the focus ring 152 is observed. Then, these observation results can be used to determine the wear-out state of the focus ring 152.

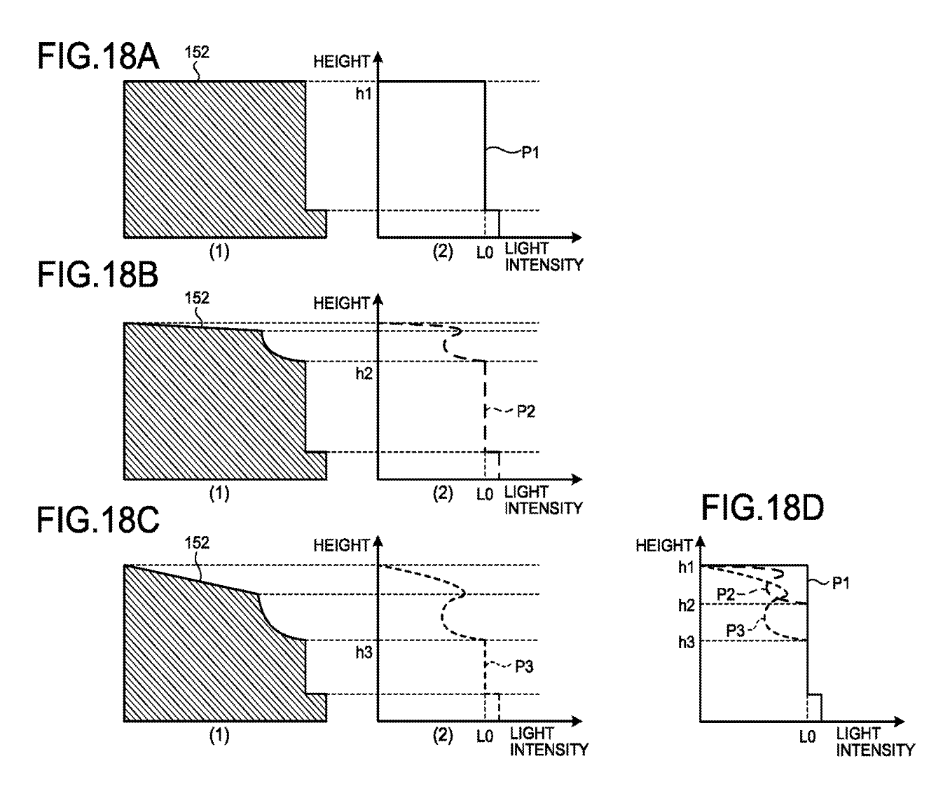

In FIG. 18A, (1) illustrates a sectional view of a state of the focus ring 152 FIG. 17A before its wear-out; (2) illustrates the relationship between light intensity and height in observation of the inner peripheral surface of the focus ring 152 of FIG. 17A before its wear-out. In FIG. 18B, (1) illustrates a sectional view of a state of the focus ring 152 of FIG. 17A in a case where its wear-out has progressed to some extent; (2) illustrates the relationship between light intensity and height in observation of the inner peripheral surface of the focus ring 152 of FIG. 17A in the case where its wear-out has progressed to some extent. In FIG. 18C, (1) illustrates a sectional view of a state of the focus ring 152 of FIG. 17A in a case where its wear-out has progressed further; (2) illustrates the relationship between light intensity and height in observation of the inner peripheral surface of the focus ring 152 of FIG. 17A in the case where its wear-out has progressed further. FIG. 18D is a diagram illustrating the relationship between light intensity and height in observation of the inner peripheral surface of the focus ring 152, in accordance with the degree of its wear-out.

As illustrated in (1) of FIG. 18A, before the focus ring 152 is worn out, the inner peripheral surface of the focus ring 152 is in an almost vertically standing state. Then, as illustrated in (1) of FIG. 18B and (1) of FIG. 18C, as wear-out of the focus ring 152 progresses, the inclination of the inner peripheral surface of the focus ring 152 becomes larger gradually.

In this case, as illustrated in (2) of FIG. 18A to (2) of FIG. 18B, by observing the inner peripheral surface of the focus ring 152, it is possible to obtain light intensity profiles P1 to P3 with respect to the height of the focus ring 152.

Here, it is assumed that the light intensity at the height hi before wear-out of the focus ring is L0. In this case, as illustrated in FIG. 18D, in the state of (1) of FIG. 18B, the light intensity at the part with heights from h1 to h2 of the focus ring 152 is lower than L0, and the wear-out state of the focus ring 152 can be estimated from the intensity variation at this part. In the state of (1) of FIG. 185, the light intensity at the part with heights from h1 to h3 of the focus ring 152 is lower than L0, and the wear-out state of the focus ring 152 can be estimated from the intensity variation at this part as in the case of (1) of FIG. 18B.

As a result, by observing the inner peripheral surface of the focus ring 152 to check the light intensity with respect to the height of the focus ring 152, it is possible to determine the height of the focus ring 152 down to which its wear-out has progressed. Then, it is possible to determine the replacement timing of the focus ring 152, by determining whether the height of the focus ring 152 down to which its wear-out has progressed reaches a predetermined value.

### Twelfth Embodiment

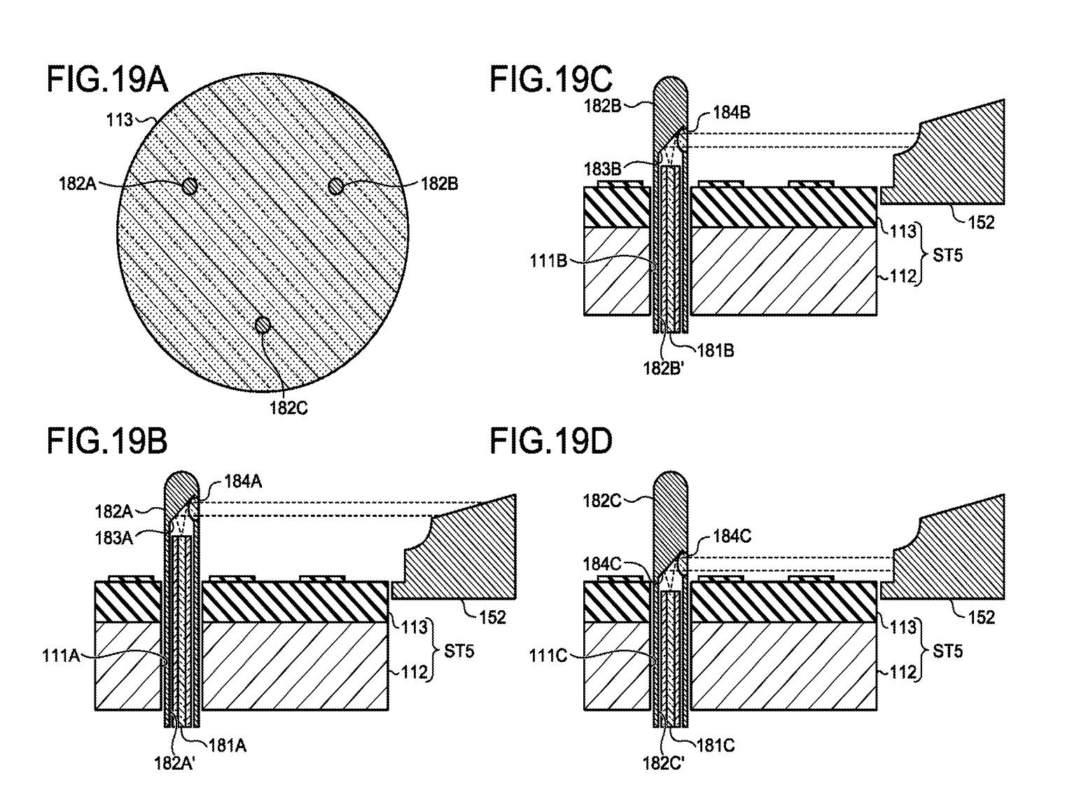

FIG. 19A is a plan view illustrating an arrangement example of pins on an electrostatic chuck applied to a plasma processing apparatus according to a twelfth embodiment. FIGS. 19B to 19D are sectional view illustrating a method of setting the height of observation of the focus ring performed by a sensing system applied to the plasma processing apparatus according to the twelfth embodiment.

As illustrated in FIG. 19A, in this plasma processing apparatus, in place of the pins 162 of FIG. 16A, pins 182A to 182C are provided. Here, optical fibers 181A to 181C are respectively inserted in the pins 182A to 182C. The pins 182A to 182C may respectively include hollows 182A′ to 182C′ in which the optical fibers 181A to 181C are inserted. Each of the hollows 182A′ to 182C′ may be formed not to penetrate the distal end of the corresponding one of the pins 182A to 182C. In the pins 182A to 1E2C, reflecting mirrors 183A to 183C are respectively arranged, such that each of them is present at the distal end of the corresponding one of the hollows 182A′ to 182C′. Light-condensing lenses 184A to 184C are respectively provided on the lateral sides of the pins 182A to 182C. Each of the light-condensing lenses 184A to 184C may be arranged between the corresponding one of the reflecting mirrors 183A to 183C and the distal end of the corresponding one of the optical fibers 181A to 181C.

Here, the distances in the height direction from the distal ends of the pins 182A to 182C to the reflecting mirrors 183A to 183C may be set different from each other. Along with this, the distances in the height direction from the distal ends of the pins 182A to 182C to the light-condensing lenses 184A to 184C may be set different from each other.

In this case, even when the pins 182A to 182C are projected upward from the stage ST5 to the same height, the pins 182A to 182C can have observation positions to the focus ring 152 different from each other in the height direction. For example, the observation positions may be set at an upper portion of the focus ring 152 by the pin 182A, at an intermediate portion of the focus ring 152 by the pin 182B, and at a lower portion of the focus ring 152 by the pin 182C.

Consequently, it is possible to improve the observation resolution on the focus ring 152, and thus to improve the determination accuracy about the wear-out state of the focus ring 152.

### Thirteenth Embodiment

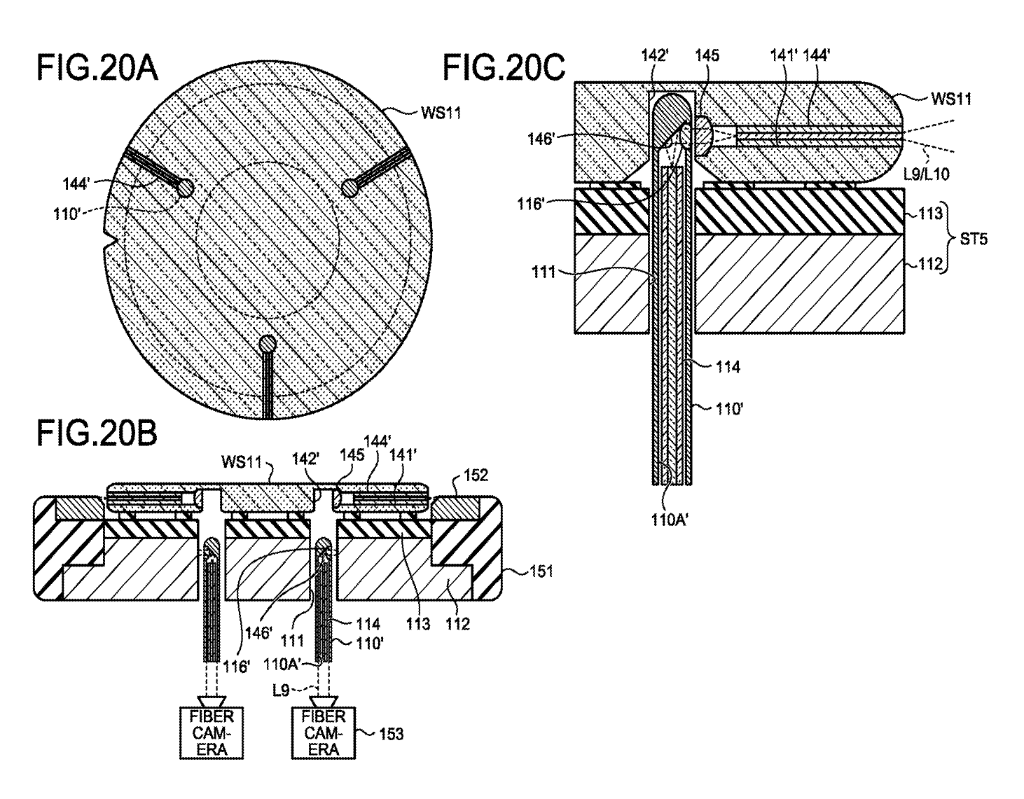

FIG. 20A is a plan view illustrating a schematic configuration of a sensing wafer to be applied to a plasma processing apparatus according to a thirteenth embodiment. FIG. 20B is a sectional view illustrating the relationship between the sensing wafer and the focus ring in a case where the sensing wafer of FIG. 20A is applied to the plasma processing apparatus. FIG. 20C is a sectional view illustrating an optical waveguide part of FIG. 20B in an enlarged state.

In the plasma processing apparatus of FIG. 20B, in place of the pins 162 of FIG. 16B, the pins 110′ of FIG. 15B are provided. In the plasma processing apparatus of FIG. 20B, when the focus ring 152 is to be observed, in place of the sensing wafer WS10 of FIGS. 15A and 15B, a sensing wafer WS11 of FIGS. 20A and 20B may be used.

In the sensing wafer WS11, in place of the passages 141 and optical fibers 144 of the sensing wafer WS10, passages 141′ and optical fibers 144′ are provided. The passages 141′ may be formed to extend from the respective pins 110′ toward end portions of the sensing wafer WS11 in the horizontal direction. The passage 141′ may be formed to open to the end portions of the sensing wafer WS11. A collimation lens 145 is arranged at the proximal end of each passage 141′. In each passage 141′, an optical fiber 144′ is provided to extend from the collimation lens 145 to the corresponding end portion of the sensing wafer WS11.

Next, an explanation will be given of a method of observing the wear-out state of the focus ring 152 by using the sensing wafer WS11.

With reference to FIG. 20B, when the sensing wafer WS11 is to he transferred into the chamber 1, the pins 110′ are projected upward from the electrostatic chuck 113. Then, the sensing wafer WS11 is transferred onto the pins 110′ to place the sensing wafer WS11 on the pins 110′. The pins 110′ are moved down in a state where the sensing wafer WS11 is placed on the pins 110′, and the sensing wafer WS11 is thereby placed onto the electrostatic chuck 113. Then, the sensing wafer WS11 is attracted by the electrostatic chuck 113, and thus the sensing wafer WS11 is fixed on the electrostatic chuck 113.

Then, when the wear-out state of the focus ring 152 is to be observed, the pins 110′ are moved up and projected upward from the electrostatic chuck 113. At this time, as illustrated in FIG. 20C, the distal end of each pin 110′ may be set to stay inside the corresponding passage 142′ of the sensing wafer WS11. Further, the collimation lenses 116′ and 145 may be set to face each other.

Then, an illumination light L9 is emitted from each fiber camera 153. The illumination light L9 comes into the corresponding optical fiber 114, is guided by this optical fiber 114 in the vertical direction, and is then reflected by the corresponding reflecting mirror 146′ to change the traveling direction of the illumination light L9 into the horizontal direction. Then, the illumination light L9 is condensed by the corresponding collimation lenses 116′ and 145, is guided by the corresponding optical fiber 144′ in the horizontal direction, and irradiates the inner peripheral surface of the focus ring 152.

When the inner peripheral surface of the focus ring 152 is irradiated with the illumination light L9, a reflection light L10 is generated from the inner peripheral surface of the focus ring 152. The reflection light L10 is guided by the corresponding optical fiber 144′ in the horizontal direction, is then condensed by the corresponding collimation lenses 116′ and 145, and is reflected by the corresponding reflecting mirror 146′ to change the traveling direction of the reflection light L10 into the vertical direction. Then, the reflection light L10 comes into the corresponding optical fiber 114, and is guided by this optical fiber 114 in the vertical direction. Then, the reflection light L10 is incident onto the corresponding fiber camera 153, by which an image of the inner peripheral surface of the focus ring 152 is generated on the basis of the reflection light L10.

The image of the inner peripheral surface of the focus ring 152 can be used to determine the wear-out state of the focus ring 152. When it is determined that the wear-out of the focus ring 152 is serious, the focus ring 152 can be replaced.

Here, as the sensing wafer WS11 is used to cause the illumination light L9 and the reflection light L10 to travel in the horizontal direction, it is possible to prevent light from the outside from mixing into the illumination light L9 and the reflection light L10. Accordingly, as compared with the method of FIG. 16C which directly irradiates the inner peripheral surface of the focus ring 152 with the illumination light L9 emitted from each pin 162, it is possible to make clearer an image of the inner peripheral surface of the focus ring 152.

### Fourteenth Embodiment

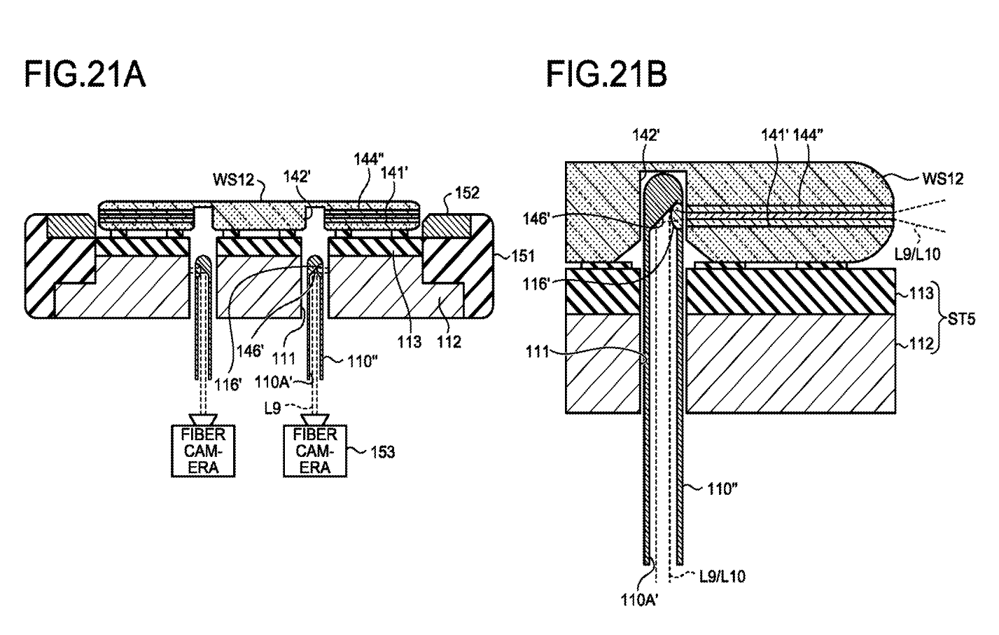

FIG. 21A is a sectional view illustrating the relationship between a sensing wafer, which is to be applied to a plasma processing apparatus according to a fourteenth embodiment, and the focus ring, in a case where the sensing wafer is applied to the plasma processing apparatus. FIG. 21B is a sectional view illustrating an optical waveguide part of FIG. 21A in an enlarged state.

In the plasma processing apparatus of FIG. 21A, in place of the pins 110′ of FIG. 20B, pins 110″ are provided. In the plasma processing apparatus of FIG. 21A, when the focus ring 152 is to be observed, in place of the sensing wafer WS11 of FIG. 20B, a sensing wafer WS12 of FIG. 21A may be used.

In the pins 110″, the optical fibers 114 inserted in the pins 110′ are omitted. In the sensing wafer WS12, the collimation lenses 145 of the sensing wafer WS11 are omitted. In each passage 141′, an optical fiber 144″ is provided to extend from the corresponding passage 142′ to an end portion of the sensing wafer WS12.

Next, an explanation will be given of a method of observing the wear-out state of the focus ring 152 by using the sensing wafer WS12.

With reference to FIG. 215, when the sensing wafer WS12 is to be transferred into the chamber 1, the pins 110″ are projected upward from the electrostatic chuck 113. Then, the sensing wafer WS12 is transferred onto the pins 110″ to place the sensing wafer WS12 on the pins 110″. The pins 110″ are moved down in a state where the sensing wafer WS12 is placed on the pins 110″, and the sensing wafer WS12 is thereby placed onto the electrostatic chuck 113. Then, the sensing wafer WS12 is attracted by the electrostatic chuck 113, and thus the sensing wafer WS12 is fixed on the electrostatic chuck 113.

Then, when the wear-out state of the focus ring 152 is to be observed, the pins 110″ are moved up and projected upward from the electrostatic chuck 113. At this time, as illustrated in FIG. 21B, the distal end of each pin 110″ may be set to stay inside the corresponding passage 142′ of the sensing wafer WS12. Further, each collimation lens 116′ may be set to face the end portion of the corresponding optical fiber 144″.

Then, an illumination light L9 emitted from each fiber camera 153. The illumination light L9 travels through the corresponding hollow 110A′ in the vertical direction, and comes into the back side of the sensing wafer WS12. Then, the illumination light L9 is reflected by the corresponding reflecting mirror 146′ to change the traveling direction of the illumination light L9 into the horizontal direction. Then, the illumination light L9 is condensed by the corresponding collimation lens 116′, is guided by the corresponding optical fiber 144′ in the horizontal direction, and irradiates the inner peripheral surface of the focus ring 152.

When the inner peripheral surface of the focus ring 152 is irradiated with the illumination light L9, a reflection light L10 is generated from the inner peripheral surface of the focus ring 152. The reflection light L10 is guided by the corresponding optical fiber 144′ in the horizontal direction, is turned into parallel light by the corresponding collimation lens 116′, and is reflected by the corresponding reflecting mirror 146′ to change the traveling direction of the reflection light L10 into the vertical direction. Then, the reflection light L10 travels through the corresponding hollow 110A′ in the vertical direction, and is incident onto the corresponding fiber camera 153, by which an image of the inner peripheral surface of the focus ring 152 is generated on the basis of the reflection light L10.

The image of the inner peripheral surface of the focus ring 152 can be used to determine the wear-out state of the focus ring 152. When it is determined that the wear-out of the focus ring 152 is serious, the focus ring 152 can be replaced.

Here, as the sensing wafer 12 is used to cause the illumination light L9 and the reflection light L10 to travel in the horizontal direction, it is possible to prevent light from the outside from mixing into the illumination light L9 and the reflection light L10. Accordingly, as compared with the method of FIG. 16C which directly irradiates the inner peripheral surface of the focus ring 152 with the illumination light L9 emitted from each pin 162, it is possible to make clearer an image of the inner peripheral surface of the focus ring 152.

Here, in the embodiments described above, an explanation has been given of a method in which the illumination light emitted from each fiber camera is caused to come into the back side of the sensing wafer by using the hollow inside the corresponding pin. In this respect, however, the pins may be set retreated outside the through holes of the stage. In this case, the illumination light emitted from each fiber camera can be guided into the back side of the sensing wafer directly through the corresponding through hole by using, for example, an optical fiber inserted into the through hole of the stage.

Further, in embodiments described above, an explanation has been given of a method in which a pin for moving a wafer up and down or a through hole for inserting the pin is used to cause light to come into back side of a sensing wafer. In this respect, however, a through hole other than the through hole for inserting the pin for moving a wafer up and down may be used to insert therein an optical fiber. For example, a through hole formed in the electrostatic chuck to supply a heat transfer medium to the back side of a wafer may be used to insert therein an optical fiber for transferring an illumination light and/or a reflection light between the fiber camera and the focus ring.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A sensing system comprising:
a waveguide configured to guide light in a wafer;
an optical system configured to cause the light guided by the waveguide to go out from a back side of the wafer; and
a detector configured to detect a state inside or outside the wafer based on a detection result about the light caused to go out by the optical system.

2. The sensing system according to claim 1, wherein the optical system is further configured to cause light that is to be guided by the waveguide to come in from the back side of the wafer.

3. The sensing system according to claim 1, wherein the waveguide is radially arranged from a central portion of the wafer toward an end portion of the wafer.

4. The sensing system according to claim 3, wherein the optical system includes a reflecting mirror arranged in the wafer, the reflecting mirror being configured to reflect the light having been guided by the waveguide in a horizontal direction into a vertical direction to cause the light to go out from the back side of the wafer.

5. The sensing system according to claim 1, wherein the waveguide includes an optical fiber embedded in the wafer.

6. The sensing system according to claim 1, wherein the waveguide includes
a trench arranged in the wafer,
a clad layer embedded in the trench, and
a core layer with a periphery surrounded by the clad layer.

7. The sensing system according to claim 1, wherein
the state inside the wafer indicates a stress distribution inside the wafer,
the state outside the wafer indicates a surface state of an electrode provided above the wafer, a distance between the wafer and the electrode, an intensity distribution of plasma above the wafer, or a wear-out state of a focus ring provided around the wafer,
the stress distribution inside the wafer is detected by using a Raman scattering light from the wafer as the light,
the surface state of the electrode or the distance between the wafer and the electrode is detected by using a reflection light from the electrode as the light,
the intensity distribution of the plasma is detected by using a light emitted from the plasma as the light, and
the wear-out state of the focus ring is detected by using a reflection light from an inner peripheral surface of the focus ring as the light.

8. The sensing system according to claim 1, further comprising an excitation light emitter or a single-crystalline semiconductor different in kind from the wafer, which is provided on the wafer and configured to emit an outgoing light based on an incoming light, wherein
the waveguide is configured to guide the incoming light to the excitation light emitter or the single-crystalline semiconductor, and to guide the outgoing light emitted from the excitation light emitter or the single-crystalline semiconductor,
the optical system is configured to cause the incoming light that is to be guided by the waveguide to come in from the back side of the wafer, and to cause the outgoing light having been guided by the waveguide to go out from the back side of the wafer, and
the detector includes a temperature calculator configured to calculate a temperature of the wafer, based on a temperature characteristic of the outgoing light caused to go out by the optical system.

9. The sensing system according to claim 8, wherein the temperature characteristic of the outgoing light is temperature dependence in decay time of the outgoing light, temperature dependence in wavelength of the outgoing light, or temperature dependence in wavelength peak intensity ratio of the outgoing light.

10. A sensing wafer comprising:
a wafer substrate;
a waveguide configured to guide light in the wafer substrate; and
an optical system configured to cause the light guided by the waveguide to go out from a back side of the wafer substrate.

11. The sensing wafer according to claim 10, further comprising an excitation light emitter or a single-crystalline semiconductor different in kind from the wafer substrate, which is provided in the wafer substrate and configured to emit an outgoing light based on an incoming light.

12. The sensing wafer according to claim 10, wherein the waveguide is radially arranged from a central portion of the wafer substrate toward an end portion of the wafer substrate.

13. The sensing wafer according to claim 10, wherein
the optical system includes a reflecting mirror arranged in the wafer substrate, the reflecting mirror being configured to reflect the light having been guided in the wafer substrate by the waveguide in a horizontal direction, into a vertical direction to cause the light to go out from the back side of the wafer substrate.

14. The sensing wafer according to claim 10, wherein the waveguide includes an optical fiber embedded in the wafer substrate.

15. The sensing wafer according to claim 16, wherein the wavequide includes
a trench arranged in the wafer substrate,
a clad layer embedded in the trench, and
a core layer with a periphery surrounded by the clad layer.

16. A plasma processing apparatus comprising:
a chamber configured to accommodate a wafer;
a wafer holder configured to hold the wafer inside the chamber;
a radio frequency power supply configured to generate plasma inside the chamber;
a through hole formed in the wafer holder; and
a waveguide or optical system configured to cause light having come in from a back side of the wafer holder through the through hole to go out from the wafer holder.

17. The plasma processing apparatus according to claim 16, further comprising a pin provided in the through hole and configured to be moved up and down, wherein
the waveguide includes an optical fiber inserted in the pin.

18. The plasma processing apparatus according to claim 17, wherein the pin includes
a hollow in which the optical fiber is inserted, and
a lens provided at a distal end of the pin.

19. The plasma processing apparatus according to claim 17, wherein the pin includes
a hollow in which the optical fiber is inserted,
a reflecting mirror provided at an end of the hollow, and
a lens provided on a lateral side of the pin at a position between the reflecting mirror and a distal end of the optical fiber.

20. The plasma processing apparatus according to claim 19, wherein the lens is configured to face an inner peripheral surface of a focus ring arranged to surround a periphery of a wafer mounting region on the wafer holder, when the pin is projected upward from the wafer holder.
